(19) United States
(12) Patent Application Publication
(10) Pub. No.: US 2010/0180176 A1
(43) Pub. Date: Jul. 15, 2010

(54) ENCODING METHOD, ENCODER, AND TRANSMITTER

(75) Inventors: Naoya Yosoku, Kanagawa (JP); Shutai Okamura, Osaka (JP); Yutaka Murakami, Osaka (JP)

Correspondence Address: Dickinson Wright PLLC;James E. Ledbetter, Esq., International Square, 1875 Eye Street, N.W., Suite 1200, Washington, DC, 20006, US

(73) Assignee: PANASONIC CORPORATION, Osaka (JP)

(21) Appl. No.: 12/377,107

(22) PCT Filed: Aug. 31, 2007
(86) PCT No.: PCT/JP2007/067067

§ 371 Date: Feb. 10, 2009

(30) Foreign Application Priority Data
Aug. 31, 2006 (JP) 2006-235204
Aug. 30, 2007 (JP) 2007-224621

(51) Int. Cl. H03M 13/05; G06F 11/10

(52) U.S. Cl. 714/752; 714/E11.032

(57) ABSTRACT

An encoding method by which an encoding speed is improved is disclosed. An encoder (100) comprises an input data storage section (107) for outputting the stored input data (D100) according to an output control signal (108), an input data count section (101) for counting the inputs of input data (D100), an output control section (102) for controlling the output destination of the input data (D100) according to the input counts, one-bit storage sections (103-1 to 103-(N−K)) for holding one-bit data, row-vector storage sections (104-1 to 104-K) for holding row vectors of an LDPC code creation matrix, vector multiplying sections (105-1 to 105-K) for multiplying a row vector and a column vector, a parity storage section (109) for holding a parity created by the multiplication, and an LDPC code-word series creating section (106); for creating an LDPC code word from the input data series and parity series and outputting it.

### TECHNICAL FIELD

The present invention relates to a coding method, coding apparatus and transmitting apparatus. In particular, the present invention relates to a coding method, coding apparatus and transmitting apparatus for generating parity bits of input data according to a check matrix of LDPC (Low Density Parity Check) codes.

### BACKGROUND ART

Up till now, as error correction codes, LDPC codes defined by parity check matrices are used. The LDPC code is an extremely sparse check matrix, that is, a linear code defined by a check matrix in which the number of nonzero elements is quite little. Direct coding is conventionally performed using such a check matrix.

To be more specific, in conventional coding, upon generating parity bits from the check matrix shown in FIG. 1, for example, the form of the check matrix is modified to reduce the number of calculations (e.g., see Non-Patent Document 1).

The LDPC check matrix in FIG. 1 is a matrix of q rows and p columns, and is formed with six submatrices A, B, C, D, E and T. In these submatrices, submatrix T is a unique matrix representing a lower triangular matrix. Here, when the check matrix in FIG. 1 is represented by H, H is expressed by following equation 1.

$$\begin{matrix}( Equation 1 ) & \\ H = [ \begin{matrix}A & B & T \\ C & D & E\end{matrix} ] & [ 1 ]\end{matrix}$$

Here, let an input bit (input data) is s, parity bits corresponding to submatrices B and D are p₁, and parity bits corresponding to submatrices T and E are p₂, following equation 2 is given.

$$\begin{matrix}( Equation 2 ) & \\ H [ \begin{matrix}s \\ {p}_{1} \\ {p}_{2}\end{matrix} ] = 0 & [ 2 ]\end{matrix}$$

Further, if H in equation 2 is multiplied by the matrix of equation 3 from the left, equation 5 is given via the expansion of equation 4.

$$\begin{matrix}( Equation 3 ) & \\ [ \begin{matrix}I & 0 \\ - {ET}^{- 1} & I\end{matrix} ] & [ 3 ] \\ \begin{matrix}( Equation 4 \text{-} 1 ) & \end{matrix} & \\ [ \begin{matrix}I & 0 \\ - {ET}^{- 1} & I\end{matrix} ] H [ \begin{matrix}s \\ {p}_{1} \\ {p}_{2}\end{matrix} ] = 0 & [ 4 ] \\ ( Equation 4 \text{-} 2 ) & \\ [ \begin{matrix}A & B & T \\ - {ET}^{- 1} A + C & - {ET}^{- 1} B + D & 0\end{matrix} ] H [ \begin{matrix}s \\ {p}_{1} \\ {p}_{2}\end{matrix} ] = 0 & \\ ( Equation 5 ) & \\ [ \begin{matrix}As + {Bp}_{1} + {Tp}_{2} \\ ( - {ET}^{- 1} A + C ) s + ( - {ET}^{- 1} B + D ) {p}_{1}\end{matrix} ] & [ 5 ]\end{matrix}$$

Here, if (−ET⁻¹B+D) in equation 5 is defined as shown in equation 6, p₁ is found from equation 7.

(Equation 6)

φ=(−ET⁻¹B+D) [6]

(Equation 7)

p₁=−φ⁻¹(−ET⁻¹A+C)s [7]

Further, equation 5 gives equation 8.

(Equation 8)

Tp₂=−(As+Bp₁) [8]

Matrix T is a lower triangular matrix, so that, by assigning equation 7 to p₁ of the right side of equation 8, it is possible to sequentially calculate p₂ of the left side from the first row.

Such calculations are performed by hardware (e.g., see Non-Patent Document 2). To be more specific, first, as shown in FIG. 2, conventional hardware performs a matrix calculation of As to calculate p₁ in equation 7. Next, to find a calculation result of T⁻¹[As], an operation for finding x that meets the condition Tx=As is performed. In this case, utilizing the fact that T is a lower triangular matrix, x is found by sequentially calculating x from the first row. This operation is referred to as “FS” (Forward Substitution). After that, the matrix calculation of −E [T⁻¹As] is performed.

Further, the hardware calculates [−ET⁻¹As]+[Cs], and calculates p₁=φ⁻¹[−ET⁻¹As+Cs]. Next, to find p₂, in equation 8, the hardware calculates Bp₁ and AS+Bp₁ in order, using p₁ calculated as above. Further, the hardware calculates p₂ by performing FS of Tp₂=−[As+Bp₁]. Thus, hardware for calculating parity bits from input data according to the above-noted operations, is provided.

### Non-Patent Document 1: Thomas J. Richardson and Rudiger L. Urbanke, “Efficient Encoding of Low-Density Parity-Check Codes,” IEEE TRANSACTION INFORMATION THEORY, VOL. 47, No. 2, FEBRUARY 2001, pp 638-656

### Non-Patent Document 2: Dong-U Lee and Wayne Luk, “A Flexible Hardware Encoder for Low-Density Parity-Check Codes,” Proceedings of the 12th Annual IEEE Symposium on Field-Programmable Custom Computing Machines (FCCM '04)

Non-Patent Document 3: Seiichi Sanpei “digital Wireless Transmission Technology,” Pearson Education

### Non-Patent Document 4: Wataru Matsumoto, Hideki Ochiai: “Application of OFDM Modulation Scheme”, Triceps

### Non-Patent Document 5: Bertland M. Hochwald and Stephan ten Brink, “Achieving Near-Capacity on a Multiple Antenna Channel,” IEEE Transaction on Communications, vol. 51, no. 3, March 2003

Non-Patent Document 6: Tadashi Wadayama “low-density parity check code and its decoding method,” Triceps

### DISCLOSURE OF INVENTION

### Problem to be Solved by the Invention

However, with the methods disclosed in Non-Patent Document 1 and Non-Patent Document 2, parity bits are found by solving recurrence equations, and, consequently, there are problems that parallel processing is difficult to perform and that, as a result, it is difficult to increase the rate of calculations upon coding.

To solve the above-noted problem, it is therefore an object of the present invention to provide a coding method, coding apparatus and transmitting apparatus for improving the rate of calculations upon coding.

### Means for Solving the Problem

To solve the above-noted problem, the present invention includes the steps of: generating a generator matrix from a check matrix in a form of a QC (Quasi Cyclic) quasi lower triangular matrix; performing a linear calculation using a submatrix of the generated matrix and input data; and outputting a parity bit of the input data by the linear calculation.

A QC matrix refers to a matrix in which, when the matrix is segmented into submatrices, all the submatrices are cyclic shifts of the identity matrix or zero matrix. Further, a quasi lower triangular matrix refers to a matrix in which submatrices in the upper right of the matrix are lower triangular matrices. Here, a lower triangular matrix refers to a matrix in which all parts in the upper right of diagonal are zero and matrix elements are in the lower left part of the diagonal.

With the above-noted configuration, by performing linear calculations of submatrices forming a generator matrix and input data, it is possible to output parity bits.

### ADVANTAGEOUS EFFECT OF THE INVENTION

According to the present invention, unlike conventional techniques, parities need not be found sequentially. That is, parities are found by performing linear calculations of submatrices of a generator matrix and input data, so that the next parity needs not be newly found using parities calculated beforehand. It is therefore possible to perform parallel processing of linear calculations and improve a coding calculation rate.

### BRIEF DESCRIPTION OF DRAWINGS

FIG. 1 illustrates an example of a check matrix used in conventional examples;

FIG. 2 illustrates a conventional example of coding processing;

FIG. 3 illustrates an example of a schematic view showing a check matrix used in the present invention;

FIG. 4 illustrates a configuration example of a coding apparatus according to Embodiment 1 of the preset invention;

FIG. 5 illustrates a configuration example of a coding apparatus according to Embodiment 2 of the present invention;

FIG. 6 illustrates a configuration example of a coding apparatus according to Embodiment 3 of the present invention;

FIG. 7 illustrates a configuration example of a coding apparatus according to Embodiment 4 of the present invention;

FIG. 8 illustrates a configuration example of a coding apparatus according to Embodiment 5 of the present invention;

FIG. 9 illustrates a configuration example of a coding apparatus according to Embodiment 6 of the present invention;

FIG. 10 illustrates a configuration example of a coding apparatus according to Embodiment 7 of the present invention;

FIG. 11 illustrates a configuration example of a coding apparatus according to Embodiment 8 of the present invention;

FIG. 12A illustrates an interleaving processing example;

FIG. 12B illustrates another interleaving processing example;

FIG. 13 illustrates a reading pattern example in a reading control section;

FIG. 14 illustrates a configuration example of a radio transmitting apparatus and radio receiving apparatus according to Embodiment 9 of the present invention;

FIG. 15 illustrates puncturing processing examples;

FIG. 16 illustrates a configuration example of a radio transmitting apparatus according to Embodiment 10 of the present invention;

FIG. 17 illustrates interleaving processing examples;

FIG. 18 illustrates an example of a schematic view of a generator matrix;

FIG. 19 illustrates a configuration example of a coding and interleaving section;

FIG. 20 illustrates a configuration example of a multi-antenna communication apparatus according to Embodiment 11 of the present invention;

FIG. 21 illustrates spatial mapping processing examples;

FIG. 22 illustrates a configuration example of a coding and spatial mapping section;

FIG. 23 illustrates an example of a schematic view of a generator matrix;

FIG. 24 illustrates a configuration example of a multi-antenna communication apparatus (on the transmitting side) according to Embodiment 12 of the present invention;

FIG. 25 illustrates a configuration example of a multi-antenna communication apparatus (on the receiving side) according to Embodiment 12 of the present invention;

FIG. 26 illustrates a factor graph according to Embodiment 12; and

FIG. 27 illustrates spatial mapping processing examples.

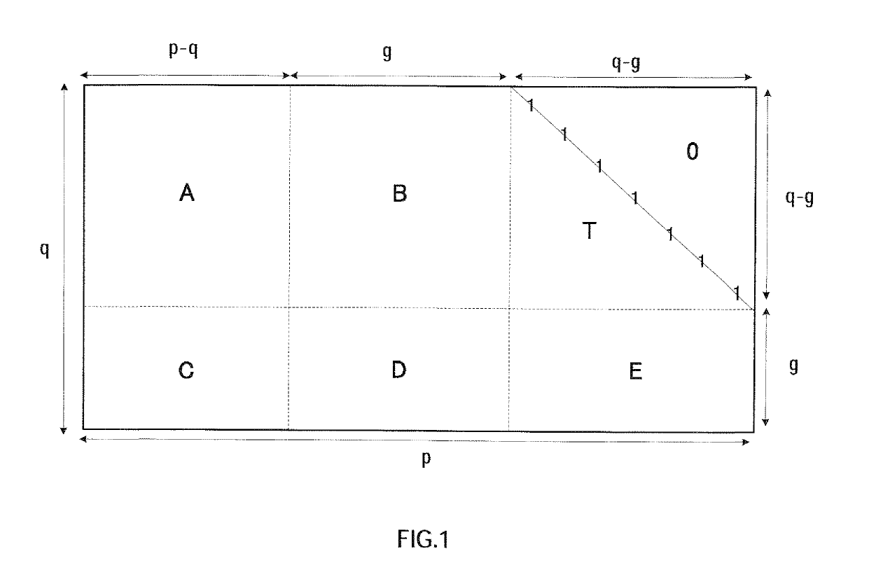

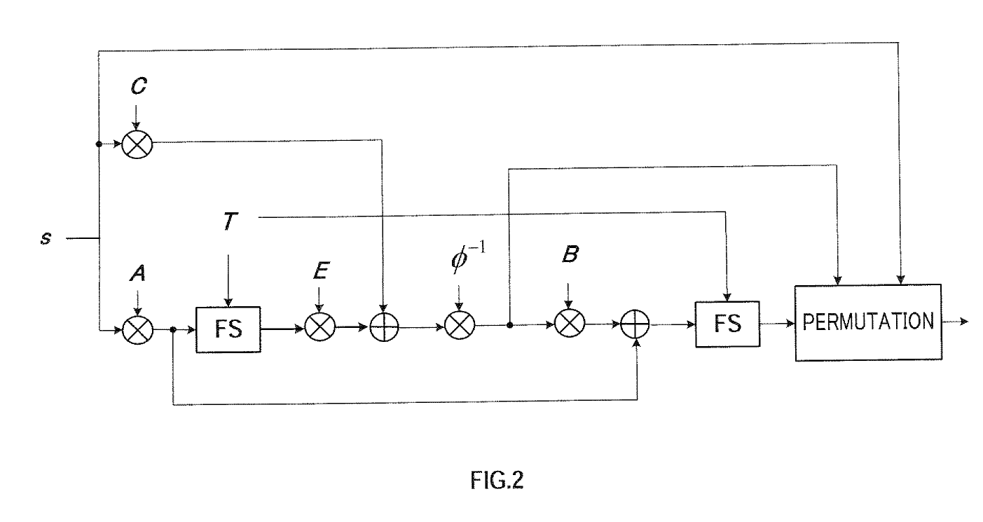

### MEANS FOR SOLVING THE PROBLEM

First, the main feature points of the present invention will be explained. A feature of the present invention lies in performing coding focusing on the fact that a submatrix forming an LDPC code generator matrix given from a QC quasi lower triangular check matrix is a sum of cyclic shifts of the identity matrix on GF(2). Here, GF(2) refers to the Galois field. The Galois field is a kind of a mathematical system used for codes. A cyclic shift is equivalent to a rotation of matrix elements. For example, the matrix shown in equation 9 is given by three cyclic shifts of the identity matrix in the right direction.

$$\begin{matrix}( Equation 9 ) & \\ {I}_{7}^{( 3 )} = [ \begin{matrix}0 & 0 & 0 & 1 & 0 & 0 & 0 \\ 0 & 0 & 0 & 0 & 1 & 0 & 0 \\ 0 & 0 & 0 & 0 & 0 & 1 & 0 \\ 0 & 0 & 0 & 0 & 0 & 0 & 1 \\ 1 & 0 & 0 & 0 & 0 & 0 & 0 \\ 0 & 1 & 0 & 0 & 0 & 0 & 0 \\ 0 & 0 & 1 & 0 & 0 & 0 & 0\end{matrix} ] & [ 9 ]\end{matrix}$$

For example, when a generator matrix is 7×7 generator matrix G₇ shown in equation 10, G₇ is expressed by a sum of cyclic shifts of the identity matrix, I₇⁽¹⁾, I₇⁽³⁾, and I₇⁽⁶⁾ like G₇=I₇⁽¹⁾+I₇⁽³⁾+I₇⁽⁶⁾. Here, I₇ represents a 7×7 identity matrix and the value in the superscript represents the amount of cyclic shifts.

$$\begin{matrix}( Equation 10 ) & \\ {G}_{7} = {I}_{7}^{( I )} ⊕ {I}_{7}^{( 3 )} ⊕ {I}_{7}^{( 6 )} = [ \begin{matrix}0 & 1 & 0 & 1 & 0 & 0 & 1 \\ 1 & 0 & 1 & 0 & 1 & 0 & 0 \\ 0 & 1 & 0 & 1 & 0 & 1 & 0 \\ 0 & 0 & 1 & 0 & 1 & 0 & 1 \\ 1 & 0 & 0 & 1 & 0 & 1 & 0 \\ 0 & 1 & 0 & 0 & 1 & 0 & 1 \\ 1 & 0 & 1 & 0 & 0 & 1 & 0\end{matrix} ] & [ 10 ]\end{matrix}$$

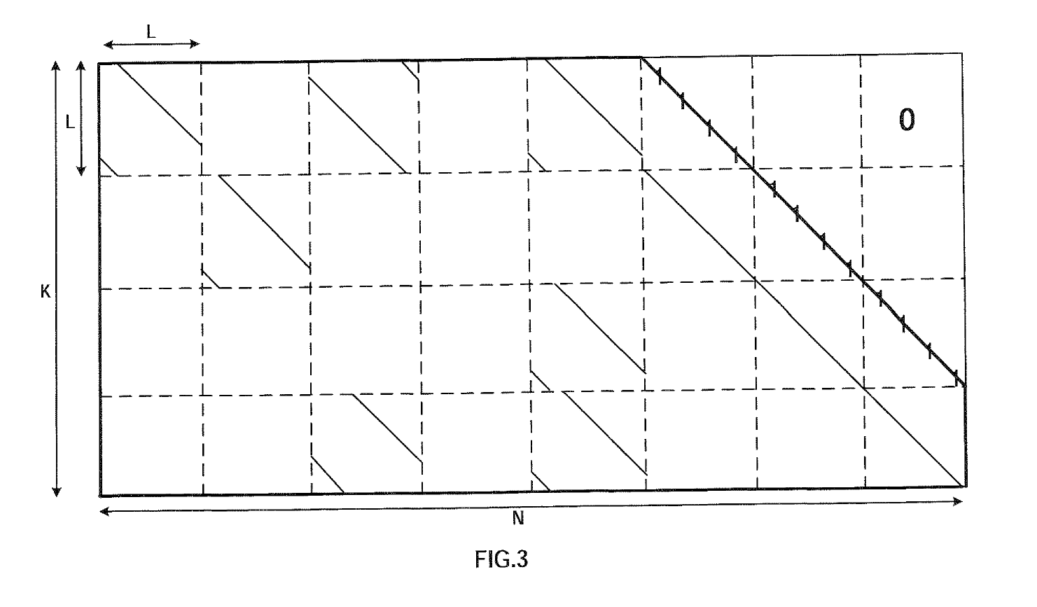

Next, the check matrix used in the present invention will be explained. The check matrix used in the present invention is a QC (Quasi Cyclic) matrix and also a matrix of a quasi lower triangular matrix (or a “QC quasi lower triangular matrix). FIG. 3 illustrates an example of a schematic view of such a check matrix.

FIG. 3 illustrates a state where a QC quasi lower triangular check matrix is segmented into L×L submatrices. In FIG. 3, the dotted lines express segments. Further, FIG. 3 shows a state where elements “1” are in the solid slash parts and elements “0” are in the other parts. The check matrix in FIG. 3 is a K×N (e.g., K=4L, N=8L) QC quasi lower triangular matrix comprised of L×L submatrices.

An example of check matrix H will be shown by equation 11. In equation 11 “-” represents zero matrices and the numeric values represent the amount of cyclic shifts of the identity matrix.

$$\begin{matrix}( Equation 11 ) & \\ H = ( \begin{matrix}0 & - & - & - & 0 & 0 & - & - & 0 & - & - & 0 & 1 & 0 & - & - & - & - & - & - & - & - & - & - \\ 22 & 0 & - & - & 17 & - & 0 & 0 & 12 & - & - & - & - & 0 & 0 & - & - & - & - & - & - & - & - & - \\ 6 & - & 0 & - & 10 & - & - & - & 24 & - & 0 & - & - & - & 0 & 0 & - & - & - & - & - & - & - & - \\ 2 & - & - & 0 & 20 & - & - & - & 25 & 0 & - & - & - & - & - & 0 & 0 & - & - & - & - & - & - & - \\ 23 & - & - & - & 3 & - & - & - & 0 & - & 9 & 11 & - & - & - & - & 0 & 0 & - & - & - & - & - & - \\ 24 & - & 23 & 1 & 17 & - & 3 & - & 10 & - & - & - & - & - & - & - & - & 0 & 0 & - & - & - & - & - \\ 25 & - & - & - & 8 & - & - & - & 7 & 18 & - & - & 0 & - & - & - & - & - & 0 & 0 & - & - & - & - \\ 13 & 24 & - & - & 0 & - & 8 & - & 6 & - & - & - & - & - & - & - & - & - & - & 0 & 0 & - & - & - \\ 7 & 20 & - & 16 & 22 & 10 & - & - & 23 & - & - & - & - & - & - & - & - & - & - & - & 0 & 0 & - & - \\ 11 & - & - & - & 19 & - & - & - & 13 & - & 3 & 17 & - & - & - & - & - & - & - & - & - & 0 & 0 & - \\ 25 & - & 8 & - & 23 & 18 & - & 14 & 9 & - & - & - & - & - & - & - & - & - & - & - & - & - & 0 & 0 \\ 3 & - & - & - & 16 & - & - & 2 & 25 & 5 & - & - & 1 & - & - & - & - & - & - & - & - & - & - & 0\end{matrix} ) & [ 11 ]\end{matrix}$$

Next, a generator matrix is found from a check matrix in the form of a QC quasi lower triangular matrix. Here, in check matrix H (K×N) in FIG. 3, when a submatrix corresponding to information bits is Hₛ (K×(N−K)) and a submatrix corresponding to parity bits is Hₚ, the relationship in equation 12 holds. Further, in equation 12, s represents the information bit sequence and p represents the parity bit sequence.

$$\begin{matrix}( Equation 12 ) & \\ [ {H}_{s} \vert {H}_{p} ] [ \frac{s}{p} ] = 0 & [ 12 ]\end{matrix}$$

Equation 12 holds in GF(2) and therefore can be modified as shown in equations 13-1 and 13-2.

(Equation 13-1)

Hₛs⊕Hₚp=0

(Equation 13-2)

Hₚp=Hₛs [13]

Here, by further expanding equation 13-2, equations 14 to 16 are given.

(Equation 14)

p=(Hₚ⁻¹Hₛ)s [14]

(Equation 15)

p=Gs [15]

(Equation 16)

(G=Hₚ⁻¹Hₛ) [16]

It is obvious from equation 15 that parity bits are uniquely found from information bits. Further, G in equation 16 represents a generator matrix for parity bits. Generator matrix G is a (K×(N−K)) matrix. As described above, it is possible to find a generator matrix for parity bits from a QC quasi lower triangular check matrix.

Further, the generator matrix for parity bits found as above is segmented into L×L submatrices. For example, when a generator matrix is given from the quasi lower triangular check matrix in FIG. 3, the generator matrix is (K×(N−K))=(4L×4L) and can be segmented into four row blocks and four column blocks. Here, a block represents a submatrix.

In this case, the block is a sum of cyclic shifts of the L×L identity matrix on GF(2) This is proven in the proof example which will be described later.

Here, for example, an example of a block in a 7×7 generator matrix is as shown in equation 10.

Upon multiplying the generator matrix and input data to get parity bits, if characteristics are utilized that the above-noted block can be expressed by a sum of cyclic shifts of the identity matrix on GF(2), it is possible to express the multiplication equation using the first column vector (hereinafter “reference vector”) of the block and cyclic shifts of the vector.

For example, let input data is sₜ (input data value: s₀, . . . , s₆, t: time), the multiplication equation for G₇ and sₜ in equation 10 can be expanded as shown in equation 17.

$$\begin{matrix}( Equation 17 ) & \\ \begin{matrix}{G}_{7} {s}_{t} = [ \begin{matrix}0 & 1 & 0 & 1 & 0 & 0 & 1 \\ 1 & 0 & 1 & 0 & 1 & 0 & 0 \\ 0 & 1 & 0 & 1 & 0 & 1 & 0 \\ 0 & 0 & 1 & 0 & 1 & 0 & 1 \\ 1 & 0 & 0 & 1 & 0 & 1 & 0 \\ 0 & 1 & 0 & 0 & 1 & 0 & 1 \\ 1 & 0 & 1 & 0 & 0 & 1 & 0\end{matrix} ] [ \begin{matrix}{s}_{0} \\ {s}_{1} \\ {s}_{2} \\ {s}_{1} \\ {s}_{4} \\ {s}_{5} \\ {s}_{6}\end{matrix} ] \\ = [ \begin{matrix}0 \\ 1 \\ 0 \\ 0 \\ 1 \\ 0 \\ 1\end{matrix} ] {s}_{0} ⊕ [ \begin{matrix}1 \\ 0 \\ 1 \\ 0 \\ 0 \\ 1 \\ 0\end{matrix} ] {s}_{1} ⊕ [ \begin{matrix}0 \\ 1 \\ 0 \\ 1 \\ 0 \\ 0 \\ 1\end{matrix} ] {s}_{2} ⊕ [ \begin{matrix}1 \\ 0 \\ 1 \\ 0 \\ 1 \\ 0 \\ 0\end{matrix} ] {s}_{3} ⊕ [ \begin{matrix}0 \\ 1 \\ 0 \\ 1 \\ 0 \\ 1 \\ 0\end{matrix} ] {s}_{4} ⊕ [ \begin{matrix}0 \\ 0 \\ 1 \\ 0 \\ 1 \\ 0 \\ 1\end{matrix} ] {s}_{5} ⊕ \\ [ \begin{matrix}1 \\ 0 \\ 0 \\ 1 \\ 0 \\ 1 \\ 0\end{matrix} ] {s}_{6}\end{matrix} & [ 17 ]\end{matrix}$$

For example, in a case of one-bit width input data, from equation 17, it is obvious that G₇sₜ can be expressed as the AND operations of the column vectors of G₇ and input data sequence, and the exclusive OR operations of the results of the AND operations. Especially the first column of G₇ is defined by the reference vector (i.e., [0100101]^{T} in equation 17 where T represents a transposed matrix). Each column vector of G₇ is expressed as a cyclic shift of reference vector. For example, in a case of input data of two-bit width as a plural-bits width, the above-noted one-bit cyclic shift may be a two-bit cyclic shift. That is, as shown in equation 17, G₇sₜ can be operated by only the AND operations of the input data sequence and the reference vector and its cyclic shift vector, and the exclusive OR operations of the results of the AND operations.

### Proof Example

Next, it will be proven that, if a generator matrix is given from the QC quasi lower triangular check matrix (or simply “check matrix”) used in the present invention, the block is a sum of cyclic shifts of the identity matrix on GF(2).

In check matrix H, submatrix Hₚ of parity bits is segmented such that M, (L×L) submatrices are provided in the row direction and column direction (K=ML). In this case, is expressed by equation 18.

$$\begin{matrix}( Equation 18 ) & \\ {H}_{p} = [ \begin{matrix}{s}_{0} & {s}_{1} & - & - & - & … & … & - \\ - & {s}_{1} & {s}_{2} & - & - & … & … & - \\ ⋮ & - & {s}_{2} & {s}_{3} & - & … & … & - \\ - & & & & & & & \\ m & & & ⋱ & & & & \\ - & & & & & & & \\ ⋮ & & & & ⋱ & & & \\ - & - & … & … & … & {s}_{M - 2} & {s}_{M - 1} & \\ {s}_{0} & - & … & … & … & … & & {s}_{M - 1}\end{matrix} ] & [ 18 ]\end{matrix}$$

However, the numeric values (elements) in check matrix Hₚ of equation 18 show the amount of cyclic shifts of the L×L identity matrix. Further, “-” represents zero matrices (L×L matrices). Further, s₀, s₁, s_{M-1} are elements located on the diagonal and are one cyclic shift from the diagonal locations. Further, in equation 18, the element in the M-th row and first column is m (s₀≠m).

Further, in equation 18, for example, the numeric value “a” in check matrix Hₚ represents a matrix shifting the L×L identity matrix to the right by “a” and inserting the elements drifted from check matrix Hₚ in the left side. The matrix in this case is shown in equation 19.

$$\begin{matrix}( Equation 19 ) & \\ {I}^{( a )} = {[ \begin{matrix} & & & & 1 & & & & \\ & & & & & 1 & & & \\ & & & & & & ⋱ & & \\ & & & & & & & 1 & \\ 1 & & & & & & & & \\ & 1 & & & & & & & \\ & & & & & & & & \\ & & & ⋱ & & & & & \\ & & & & 1 & & & & \end{matrix} ]}^{\begin{matrix}1 & 2 & … & a + 1 & … & L\end{matrix}} & [ 19 ]\end{matrix}$$

Further, if “a” is a negative value, it is expressed that leftward cyclic shifts are performed.

First, an inverse matrix of Hₚ is found. Here, if the inverse matrix of Hₚ is A, and, similar to Hₚ, segmented into L×L submatrices, Hₚ can be expressed as shown in equation 20.

$$\begin{matrix}( Equation 20 ) & \\ [ \begin{matrix}{A}_{1 , 1} {A}_{1 , 2} & … & {A}_{1 , M} \\ {A}_{2 , 1} {A}_{2 , 2} & … & {A}_{2 , M} \\ & … & \\ {A}_{M , 1} {A}_{M , 2} & … & {A}_{M , M}\end{matrix} ] {H}_{p} = {I}_{M} & [ 20 ]\end{matrix}$$

However, in equation 20, I_{M} shows an M×M identity matrix.

Here, there is a characteristic that, if a given matrix and a cyclic shift of the identity matrix are multiplied, a cyclic shift of the given matrix is given. Therefore, let a given matrix is B and a cyclic shift of the identity matrix is I^{(b)}, the multiplication result of B and I^{(b)} can be expressed as shown in equation 21.

$$\begin{matrix}( Equation 21 ) & \\ \begin{matrix}{BI}^{( b )} = [ \begin{matrix}{b}_{1 , 1} {b}_{1 , 2} & … & {b}_{1 , L} \\ {b}_{2 , 1} {b}_{2 , 2} & … & {b}_{2 , L} \\ & … & \\ {b}_{L , 1} {b}_{L , 2} & … & {b}_{L , L}\end{matrix} ] {I}^{( b )} \\ = [ \begin{matrix}{b}_{1 , L - b + 1} {b}_{1 , L - b + 2} & … & {b}_{1 , L - b} \\ {b}_{2 , L - b + 1} {b}_{2 , L - b + 2} & … & {b}_{2 , L - b} \\ … & & \\ {b}_{L , L - b + 1} {b}_{L , L - b + 2} & … & {b}_{L , L - b}\end{matrix} ] \\ = {B}^{( b )}\end{matrix} & [ 21 ]\end{matrix}$$

Next, utilizing the relationship shown in equation 21, if the left side of equation 20 is expanded about submatrices A_{k,1}, A_{k,2}, . . . , A_{k,M} of the k-th stage of A, equation 22 is given.

$$\begin{matrix}( Equation 22 ) & \\ \{ \begin{matrix}{A}_{k , 1}^{( {s}_{0} )} ⊕ {A}_{k , N}^{( m )} ⊕ {A}_{k , M}^{( {s}_{0} )} \\ {A}_{k , 1}^{( {s}_{1} )} ⊕ {A}_{k , 2}^{( {s}_{1} )} \\ {A}_{k , 2}^{( {s}_{2} )} ⊕ {A}_{k , 3}^{( {s}_{2} )} \\ … \\ {A}_{k , M - 1}^{( {s}_{M - 1} )} ⊕ {A}_{k , M}^{( {s}_{M - 1} )}\end{matrix} & [ 22 ]\end{matrix}$$

Here, in the following, A_{k,x} in equation 22 is expressed by Aₓ. The collection of submatrices in the k-th stage of A is focused, and, consequently, the value of the right side of equation 22 varies depending on the value of k. Therefore, in the following, the inverse matrix is found according to patterns of k values.

First, the inverse matrix in the case of k=1 is found (see equations 23-1 to 23-3).

$$\begin{matrix}( Equation 23 \text{-} 1 ) \\ {A}_{1}^{( {s}_{0} )} ⊕ {A}_{N}^{( m )} ⊕ {A}_{M}^{( {s}_{0} )} = I \\ ( Equation 23 \text{-} 2 ) \\ {A}_{1}^{( {s}_{1} )} ⊕ {A}_{2}^{( {s}_{1} )} = 0 \\ ( Equation 23 \text{-} 3 ) \\ {A}_{2}^{( {s}_{2} )} ⊕ {A}_{3}^{( {s}_{2} )} = 0 \\ ⋮ \\ ( Equation 23 \text{-} M ) \\ {A}_{M - 1}^{( {s}_{M - 1} )} ⊕ {A}_{M}^{( {s}_{M - 1} )} = 0\end{matrix} \qquad [ 23 ]$$

Here, by assigning equation 24 to equation 23-1, equation 25 is given.

(Equation 24)

A₁=A₂= . . . =A_{M} [24]

(Equation 25)

A₁^{(s}^{₀}⁾⊕A₁^{(m)}⊕A₁^{(s}^{₀}⁾=I

A₁^{(m)}=I

∴A₁=A₁= . . . =A_{M}=I^{(-m)} [25]

Next, the inverse matrix in the case of 2≦k≦N is found (see equations 26-1 to 26-M).

$$\begin{matrix}( Equation 26 \text{-} 1 ) & [ 26 ] \\ ii ) 2 \leq k \leq N & \\ {A}_{1}^{( {s}_{0} )} ⊕ {A}_{N}^{( m )} ⊕ {A}_{M}^{( {s}_{0} )} = 0 & \\ ( Equation 26 \text{-} 2 ) & \\ {A}_{1}^{( {s}_{1} )} ⊕ {A}_{2}^{( {s}_{1} )} = 0 & \\ ( Equation 26 \text{-} 3 ) & \\ {A}_{2}^{( {s}_{2} )} ⊕ {A}_{3}^{( {s}_{2} )} = 0 \\ ⋮ & \\ ( Equation 26 \text{-} k ) & \\ {A}_{k - 1}^{( {s}_{k - 1} )} ⊕ {A}_{k}^{( {s}_{k - 1} )} = I \\ ⋮ & \\ ( Equation 26 \text{-} N ) & \\ {A}_{N - 1}^{( {s}_{N - 1} )} ⊕ {A}_{N}^{( {s}_{N - 1} )} = 0 \\ ⋮ & \\ ( Equation 26 \text{-} M ) & \\ {A}_{M - 1}^{( {s}_{M - 1} )} ⊕ {A}_{M}^{( {s}_{M - 1} )} = 0 & \end{matrix}$$

Here, by assigning equations 27 and 28 to equations 26-1 and 26-k, respectively, equations 29-1 and 29-2 are given.

(Equation 27)

A₁=A₂= . . . =Aₖ₋₁ [27]

(Equation 28)

Aₖ=Aₖ₊₁= . . . =A_{N}= . . . =A_{M} [28]

(Equation 29-1)

A₁^{(s}^{₀}⁾⊕A_{M}^{(m)}⊕A_{M}^{(s}^{₀}⁾=0

(Equation 29-2)

A₁^{(S}^{_{k−1}}⁾⊕A_{M}^{(s}^{_{k−1}}⁾=I [29]

Here, equation 29-1 gives equation 30.

(Equation 30)

A₁^{(S}^{₀}⁾⊕A_{M}^{(S}^{₀}⁾=I^{(S}^{₀}^{-s}^{_{k−1}}⁾ [30]

Here, by assigning equation 30 to equation 29-1, equation 31 is found.

(Equation 31-1)

A_{M}^{(m)}=I^{(S}^{₀}^{-s}^{_{k−1}}⁾

∴Aₖ=Aₖ₊₁= . . . =A_{N}= . . . =A_{M}=I^{(S}^{₀}^{-s}^{_{k−1}}^{-m)}

(Equation 31-2)

A₁^{(s}^{_{k−1}}⁾=I⊕I^{(S}^{₀}^{-s}^{_{k−1}}^{-m)}

∴A₁=A₂= . . . Aₖ₋₁=I^{(-s}^{_{k−1}}⁾⊕I^{(S}^{₀}^{-2s}^{_{k−1}}^{-m)} [31]

Next, the inverse matrix in the case of N<k≦M is found (see equations 32-1 to 32-M).

$$\begin{matrix}( Equation 32 \text{-} 1 ) & [ 32 ] \\ iii ) N < k \leq M & \\ {A}_{1}^{( {s}_{0} )} ⊕ {A}_{N}^{( m )} ⊕ {A}_{M}^{( {s}_{0} )} = 0 & \\ ( Equation 32 \text{-} 2 ) & \\ {A}_{1}^{( {s}_{1} )} ⊕ {A}_{2}^{( {s}_{1} )} = 0 & \\ ( Equation 32 \text{-} 3 ) & \\ {A}_{2}^{( {s}_{2} )} ⊕ {A}_{3}^{( {s}_{2} )} = 0 \\ ⋮ & \\ ( Equation 32 \text{-} k ) & \\ {A}_{N - 1}^{( {s}_{N - 1} )} ⊕ {A}_{N}^{( {s}_{N - 1} )} = 0 \\ ⋮ & \\ ( Equation 32 \text{-} N ) & \\ {A}_{k - 1}^{( {s}_{k - 1} )} ⊕ {A}_{k}^{( {s}_{k - 1} )} = I \\ ⋮ & \\ ( Equation 32 \text{-} M ) & \\ {A}_{M - 1}^{( {s}_{M - 1} )} ⊕ {A}_{M}^{( {s}_{M - 1} )} = 0 & \end{matrix}$$

Here, equations 32-1 to 32-(k−1) give equation 33-1. Further, equations 32-(k+1) to 32-M give equation 33-2.

(Equation 33-1)

A₁=A₂= . . . =A_{N}= . . . =Aₖ₋₁

(Equation 33-2)

Aₖ=Aₖ₊₁= . . . =A_{M} [33]

Here, by assigning equations 33-1 and 33-2 to equations 32-1 and 32-k, respectively, equations 34-1 and 34-2 are given.

(Equation 34-1)

A₁^{(s}^{₀}⁾⊕A₁^{(m)}⊕A_{M}^{(s}^{₀}⁾=0

(Equation 34-2)

A₁^{(S}^{_{k−1}}⁾⊕A_{M}^{(s}^{_{k−1}}⁾=I [34]

Here, equation 34-2 gives equation 35.

(Equation 35)

A₁^{(S}^{₀}⁾⊕A_{M}^{(S}^{₀}⁾=I^{(S}^{₀}^{-s}^{_{k−1}}⁾ [35]

Here, by assigning equation 35 to equation 34-1, equation 36-1 is given. Further, by assigning equation 36-1 to equation 34-2, equation 36-2 is given.

(Equation 36-1)

A_{M}^{(m)}=I^{(S}^{₀}^{-s}^{_{k−1}}⁾

∴Aₖ=Aₖ₊₁= . . . =A_{N}= . . . =A_{M}=I^{(S}^{₀}^{-s}^{_{k−1}}^{-m)}

(Equation 36-2)

A₁^{(s}^{_{k−1}}⁾=I⊕I^{(S}^{₀}^{-s}^{_{k−1}}^{-m)}

∴A₁=A₂= . . . Aₖ₋₁=I^{(-s}^{_{k−1}}⁾⊕I^{(S}^{₀}^{-2s}^{_{k−1}}^{-m)} [36]

In view of the above, constituent submatrices (L×L matrices) of the inverse matrix of Hₚ can be all expressed by addition of cyclic shifts of the identity matrix on GF(2).

Further, generator matrix G in equation 15 can be expressed by multiplication of the inverse matrix of submatrix Hₚ corresponding to parity bits of check matrix H by submatrix Hₛ of input information bits. In this case, if Hₛ is segmented into constituent submatrices (L×L matrices), when these L×L matrices can be each expressed by a sum of cyclic shifts of the identity matrix on GF(2), according to the relationship in equation 21, it is equally possible to express constituent submatrices of the G matrix (L×L matrices) by addition of cyclic shifts of the identity matrix on GF(2).

### (QED)

Further, even if the columns of the constituent submatrices of Hₚ shown in equation 18 are replaced, the above-noted proof is equally established. Further, even if the first column of equation 18 is replaced in the row direction, the above-noted proof is equally established.

Here, an example of replacing the columns of the constituent submatrices in equation 18 is shown in equation 37, equation 38.

$$\begin{matrix}( Equation 37 ) & \\ {H}_{p} = [ \begin{matrix}- & - & n & … & {s}_{1} & - & - \\ {s}_{2} & ⋮ & - & … & {s}_{1} & ⋮ & - \\ {s}_{2} & ⋮ & ⋮ & … & - & ⋮ & {s}_{3} \\ - & ⋮ & - & … & ⋮ & ⋮ & {s}_{3} \\ ⋮ & ⋮ & m & … & ⋮ & ⋮ & - \\ ⋮ & ⋮ & - & … & ⋮ & - & ⋮ \\ ⋮ & - & ⋮ & … & ⋮ & {s}_{M - 2} & ⋮ \\ ⋮ & {s}_{M - 1} & - & … & ⋮ & {s}_{M - 2} & ⋮ \\ - & {s}_{M - 1} & n & … & - & - & -\end{matrix} ] & [ 37 ] \\ ( Equation 38 ) & \\ {H}_{p} = [ \begin{matrix}- & - & - & … & {s}_{1} & - & - \\ {s}_{2} & ⋮ & m & … & {s}_{1} & ⋮ & - \\ {s}_{2} & ⋮ & - & … & - & ⋮ & {s}_{3} \\ - & ⋮ & n & … & ⋮ & ⋮ & {s}_{3} \\ ⋮ & ⋮ & - & … & ⋮ & ⋮ & - \\ ⋮ & ⋮ & - & … & ⋮ & - & ⋮ \\ ⋮ & - & ⋮ & … & ⋮ & {s}_{M - 2} & ⋮ \\ ⋮ & {s}_{M - 1} & n & … & ⋮ & {s}_{M - 2} & ⋮ \\ - & {s}_{M - 1} & - & … & - & - & -\end{matrix} ] & [ 38 ]\end{matrix}$$

Based on the above explanations, embodiments of the present invention will be explained below with reference to the accompanying drawings.

### Embodiment 1

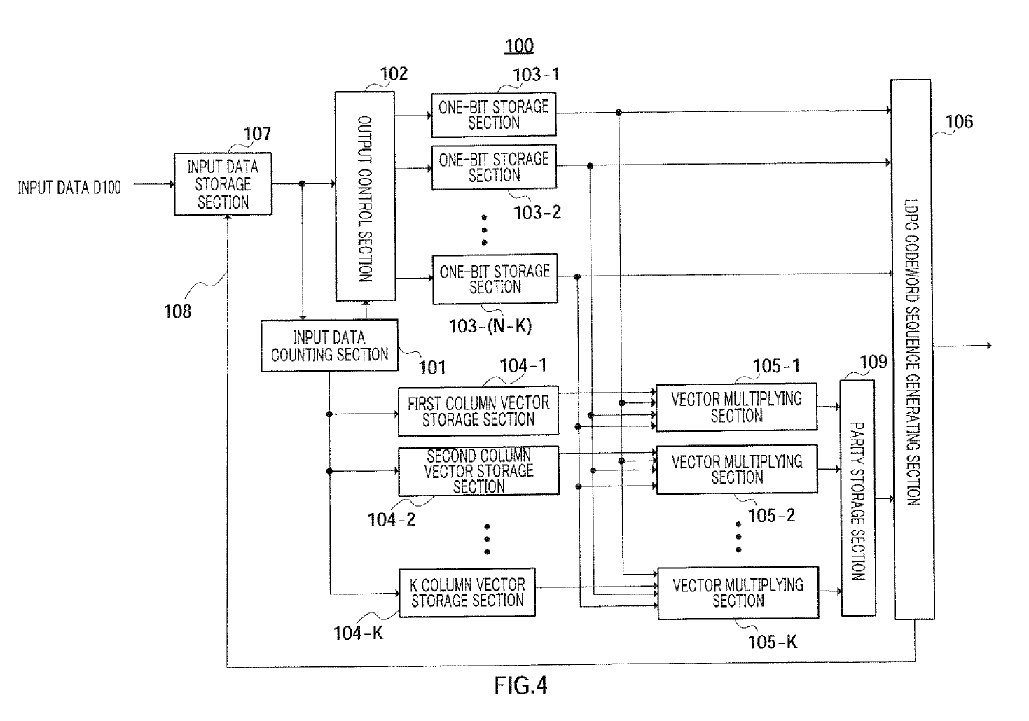

FIG. 4 illustrates a configuration example of the coding apparatus according to Embodiment 1 of the present invention. With the present embodiment, an LDPC codeword is given by multiplying row vectors of an LDPC code generator matrix and an input data sequence used as column vectors. By employing the above-noted configuration, the present embodiment provides a feature of being able to acquire parities of LDPC codes at the same time and perform fast coding.

Further, with the present embodiment, before generating parity data from input data, the input data is stored once in the coding apparatus, to output the parity data provided after (or before) the input data and synchronize timings to generate LDPC codes, upon generating an LDPC codeword.

For example, when input data is all inputted into the coding apparatus, by the time parity data is generated, a generated delay amount determined by the coding apparatus is given. Here, to generate LDPC codes by aligning input data and parity data and output the codes at synchronized timing, the coding apparatus needs an input data storage section to store the input data.

Further, to output the aligned input data and parity data, the timing to read out input data from the input data storage section needs to be generated. For example, in the coding apparatus, when parity data is generated and an LDPC codeword sequence generating section is able to provide the parity data after (or before) input data to make and output an LDPC code sequence, the timing to read out the input data from the input data storage section is generated and the input data is read by the input storage section using that timing.

With the above-noted operations, it is possible to output LDPC codes in order from input data, first, and parity data, next. Further, the above-noted input data storage section is equivalent to input data storage section 107 in coding apparatus 100 in FIG. 4 and the above-noted timing to read out input data is equivalent to output control signal 108. These input data storage section 107 and output control signal 108 have the above-noted similar functions in the following embodiments.

Explanations will be shown below using figures. Coding apparatus 100 of FIG. 4 is provided with input data counting section (or “counting section”) 101, output control section 102, one-bit storage sections 103-1 to 103-(N−K), row vector storage sections 104-1 to 104-K, vector multiplying sections 105-1 to 105-K, LDPC codeword sequence generating section 106, input data storage section 107 and parity bit storage section 109. In coding apparatus 100, sections 101 to 105 are collectively referred to as a parity generating section. Further, the parity generating section and sections 106 and 109 are collectively referred to as an LDPC codeword generating section (or codeword generating section).

Further, with the present embodiment, one-bit storage sections 103-1 to 103-(N−K), row vector storage sections 104-1 to 104-K, and vector multiplying sections 105-1 to 105-K are also referred to as one-bit storage sections 103, row vector storage sections 104 and vector multiplying sections 105, respectively.

The functions of the sections of coding apparatus 100 in FIG. 4 will be briefly explained. Input data storage section 107 stores input data and outputs the stored input data to input data counting section 101 and output control section 102 according to output control signal 108. Input data counting section 101 has a function for counting the number of times input data D101 is inputted in coding apparatus 100. Output control section 102 has a function for controlling the output destination of input data depending on the number of times data is inputted. One-bit storage sections 103 have a function for holding one-bit data. Row vector storage sections 104 hold row vectors of a generator matrix of LDPC codes generated in coding apparatus 100. For example, in a case of the x-th (x is a natural number) row vector of the generator matrix, the vector is stored in row vector storage section 104-X.

Vector multiplying sections 105 have a function for multiplying row vectors and column vectors. To be more specific, vector multiplying section 105-X multiplies the X-th row vector of the generator matrix and input data vector. Parity storage section 109 has a function for holding a parity sequence generated in coding apparatus 100. LDPC codeword sequence generating section 106 has a function for generating an LDPC codeword from the input data sequence and the parity sequence generated in coding apparatus 100 and outputting the LDPC codeword.

Next, the coding according to the present embodiment will be explained in detail. In coding apparatus 100 in FIG. 4, input data storage section 107 stores input data D100. The data stored in input data storage section 107 is outputted to input data counting section 101 and output control section 102 according to output control signal 108. Output control signal 108 controls input data storage section 107 to output storage data (data in input data storage section 107) to input data counting section 101 and output control section 102 after parity data is generated from input data D100, converted into an LDPC code sequence and outputted in coding apparatus 100. By this means, it is possible to control input data D100 not to be inputted in the LDPC codeword generating section before parity data is generated and outputted.

Input data counting section 101 counts and outputs the number of times input data D101 is received as input.

Output control section 102 controls the output destination of input data D100 according to the output of input data counting section 101, that is, according to the count. To be more specific, for example, when the count of inputs is one, input data D100 is outputted to one-bit storage section 103-1. Further, when the count is two, output control section 102 outputs input data D100 to one-bit storage section 103-2, and, in the same way as above, sequentially outputs input data D100 to respective one-bit storage sections until the count of input data D100 reaches (N−K). Here, (N−K) is equivalent to the number of columns of the generator matrix. As described above, by storing an input data sequence of (N−K) bits in one-bit storage sections, it is possible to use the input data sequence as a column vector.

Next, when the count as the output from input data counting section 101 is (N−K), row vector storage sections 104 output the stored row vectors. Vector multiplying sections 105 multiply the row vectors outputted from row vector storage sections 104 and the input data sequence outputted from one-bit storage sections 103-1 to 103-(N−K), and outputs the results to parity storage section 109. Here, the input data sequence has (N−K) bits and consequently can be used as an input data vector. The output results in this case are equivalent to parity bits.

LDPC codeword sequence generating section 106 aligns the data outputted from one-bit storage sections 103-1 to 103-(N−K) in order from the 103-1 output (indicating the output from one-bit storage section 103-1), 103-2 output, . . . , 103-(N−K) output, and outputs the aligned data. Further, after that, LDPC codeword sequence generating section 106 aligns the parity bits outputted from vector multiplying sections 105-1 to 105-K in order, and outputs the aligned parity bits. For example, alignment is performed in order from the output parity bit from vector multiplying section 105-1, output parity bit from vector multiplying section 105-2, . . . , output parity bit from vector multiplying section 105-K, and these output parity bits are outputted. By adopting the above-noted output method, the outputs from LDPC codeword sequence generating section 106 can be arranged in order from data bits and parity bits.

As described above, according to the present embodiment, by employing a configuration multiplying row vectors of an LDPC code generator matrix and input data sequence used as a column vector, it is possible to find parities of LDPC codes at the same time and perform fast coding.

### Embodiment 2

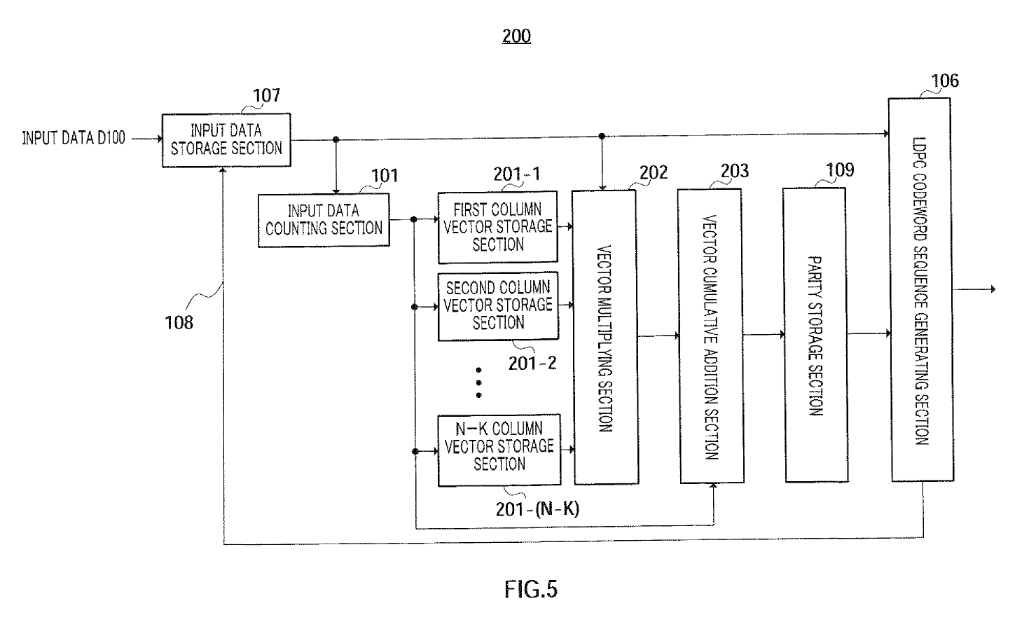

FIG. 5 illustrates a configuration example of coding apparatus 200 according to Embodiment 2 of the present invention. Further, in Embodiment 2, the same components as in Embodiment 1 will be assigned the same reference numerals (including terminology) and overlapping explanations will be omitted adequately.

According to the present embodiment, a parity is found by multiplying column vectors of a generator matrix and input data and cumulatively adding the results. According to the present embodiment, a generator matrix and input data are multiplied using the column vectors of the generator matrix. Therefore, it is not necessary to hold input data upon multiplication and generate input data vectors. As described above, a feature of coding apparatus 200 according to the present embodiment lies in reducing the circuit scale since a storage section for input data is not necessary, and in performing fast coding since a parity can be found when input data is all inputted.

The present embodiment will be explained below in detail using a drawing. Unlike Embodiment 1, coding apparatus 200 of FIG. 5 has column vector storage sections 201-1 to 201-(N−K), vector multiplying section 202 and vector cumulative addition section 203. Further, vector multiplying section 202 has a different function from vector multiplying section 105 in Embodiment 1, and is therefore assigned a different code. In the present embodiment, sections 101 and 201 to 203 are collectively referred to as a parity generating section. Further, the parity generating section and sections 106 and 109 are collectively referred to as an LDPC codeword generating section.

Further, according to the present embodiment, column vector storage sections 201-1 to 201-(N−K) can be equally expressed by column vector storage sections 201.

Next, the functions of the sections of the coding apparatus of FIG. 5 will be briefly explained. Column vector storage sections 201-1 to 201-(N−K) hold vectors of the first column to (N−K)-th column of a generator matrix to generate LDPC codes. Here, the generator matrix used in the present embodiment has (N−K) columns.

Vector multiplying section 202 has a function for multiplying one bit of input data and the column vectors. In this case, vector multiplying section 202 employs a configuration outputting the input column vector as is when input data is “1” and outputting a zero vector when the input data is “0.” Vector cumulative addition section 203 has a function for cumulatively adding input vectors.

Next, the present embodiment will be explained in detail. As Embodiment 1, input data D100 is held in input data storage section 107 and is outputted according to output control signal 108.

Column vector storage sections 201-1 to 201-(N−K) output stored column vectors of the generator matrix according to the count of input data is inputted from input data counting section 101. For example, when the count is one, first column vector storage section 201-1 outputs the first vector of the generator matrix and the other column vector storage sections output nothing. When the count is X (X is a natural number), X-th column vector storage section 201-X outputs the X-th column vector of the generator matrix and the other column vector storage sections output nothing. Thus, a column vector of the generator matrix is outputted according to the count.

Vector multiplying section 202 multiplies the input data outputted from input data storage section 107 and the column vector of the generator matrix outputted from column vector storage sections 201-1 to 201-(N−K) according to the count of input data is inputted, and outputs the result. The column vector of the generator matrix outputted from column vector storage sections 201 is outputted according to the count of input data is inputted. Therefore, in multiplication of the input data and column vector, an associated column vector in the generator matrix is used.

Vector cumulative addition section 203 resets the cumulatively added vector when the count of input data is inputted from input data counting section 101 is zero. When the count of input data is inputted is not zero, a vector inputted from vector multiplying section 202 is cumulatively added.

For example, when the output of vector multiplying section 202 is [0, 1, 1, 0, 0, 1, 0]^{T} and the cumulatively added vector is [1, 1, 1, 0, 0, 1, 0,]^{T}, the cumulative sum vector is [1, 0, 0, 0, 0, 0, 0]^{T}.

Further, vector cumulative addition section 203 outputs a vector cumulatively adding the output from vector multiplying section 202 when the count of input data is equal to the number of columns of the generator matrix. Here, this output vector is parity data.

As in Embodiment 1, parity storage section 109 stores the parity data generated in vector cumulative addition section 203. Further, LDPC codeword sequence generating section 106 aligns in correct order the input data and generated parity data, and outputs these data. Further, when finishing outputting the input data and parity data, LDPC codeword sequence generating section 106 outputs output control signal 108 to input data storage section 107.

By employing the above-described configuration, it is not necessary to store input data upon multiplying input data and generator matrix to generate input data vectors, so that it is possible to reduce the circuit scale since a storage section for input data is not necessary. Further, by acquiring parity at the time when input data is all inputted, it is possible to perform fast coding.

### Embodiment 3

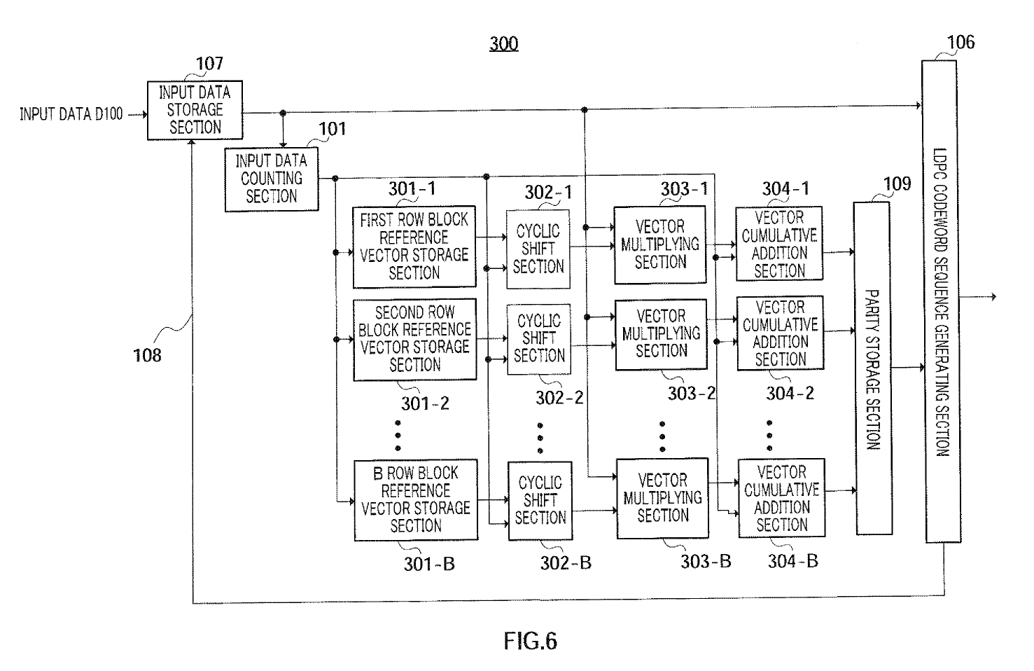

FIG. 6 shows a configuration example of coding apparatus 300 according to Embodiment 3 of the present invention. Further, in Embodiment 3, the same components as in Embodiment 1 will be assigned the same reference numerals (including terminology) and overlapping explanations will be omitted adequately.

According to the present embodiment, parity data is found by multiplying a generator matrix given from a QC (Quasi Cyclic) quasi lower triangular check matrix and input data. Further, to perform LDPC coding, the reference vectors of blocks of a generator matrix are used. In multiplication of the generator matrix and input data, parity data is found by multiplying cyclic shifts of the reference vectors of blocks in a generator matrix and input data and cumulatively adding the results. By employing the above-noted configuration, in coding apparatus 300, it is possible to reduce the circuit scale for reproducing the generator matrix for LDPC codes. Further, coding apparatus 300 needs not find a new parity using given parities and can perform processing for coding in parallel, thereby enabling fast coding.

The present embodiment will be explained below using a drawing. Unlike Embodiment 1, coding apparatus 300 in FIG. 6 has row block reference vector storage sections (or row reference storage sections) 301-1 to 301-B, cyclic shift sections 302-1 to 302-B, vector multiplying sections 303-1 to 303-B, and vector cumulative addition sections 304-1 to 304-B. In the present embodiment, sections 101 and 301 to 304 are collectively referred to as a parity generating section. Further, the parity generating section and sections 106 and 109 are collectively referred to as an LDPC codeword generating section.

Further, in the present embodiment, row block reference vector storage sections 301-1 to 301-B, cyclic shift sections 302-1 to 302-B, vector multiplying sections 303-1 to 303-B and vector cumulative addition sections 304-1 to 304-B are also referred to as block reference vector storage sections 301, cyclic shift sections 302, vector multiplying sections 303, and vector cumulative addition sections 304, respectively.

The functions of the sections of coding apparatus 300 in FIG. 6 will be briefly explained. Row block reference vector storage sections 301-1 to 301-B store reference vectors of row blocks in a generator matrix for performing LDPC coding. The generator matrix used in the present embodiment is a generator matrix acquired from a QC (Quasi Cyclic) quasi lower triangular check matrix.

Here, the row blocks in the generator matrix refer to blocks provided in the row direction when the generator matrix is segmented into blocks. For example, when generator matrix G is segmented into three row blocks and four column blocks as shown in equation 39, in the row blocks in the generator matrix, G₁₁, G₁₂, G₁₃ and G₁₄ are referred to as first row blocks, G₂₁, G₂₂, G₂₃ and G₂₄ are referred to as second row blocks, and G₃₁, G₃₂, G₃₃ and G₃₄ are referred to as third row blocks.

$$\begin{matrix}( Equation 39 ) & \\ G = [ \begin{matrix}{G}_{11} & {G}_{12} & {G}_{13} & {G}_{14} \\ {G}_{21} & {G}_{22} & {G}_{23} & {G}_{24} \\ {G}_{31} & {G}_{32} & {G}_{33} & {G}_{34}\end{matrix} ] & [ 39 ]\end{matrix}$$

For example, first row block reference vector storage section 301-1 stores the reference vectors of G₁₁, G₁₂, G₁₃ and G₁₄. Further, assume that the generator matrix of the present embodiment has B row blocks (B=K/L).

Cyclic shift sections 302-1 to 302-B cyclically shift inputted reference vectors and output the cyclically shifted reference vectors to vector multiplying sections 303-1 to 303-B. Vector multiplying sections 303-1 to 303-B multiply the cyclically shifted reference vectors and input data vector, and output the multiplied vectors to vector cumulative addition sections 304-1 to 304-B. Vector cumulative addition sections 304-1 to 304-B output the cumulative sum of the input vectors.

Next, the present embodiment will be explained in detail. Coding apparatus 300 in FIG. 6 is similar to in Embodiments 1 and 2 in receiving input data D100, rearranging generated parity and input data in the correct order and outputting the result as an LDPC codeword. The present embodiment is different from Embodiments 1 and 2 in the processing method of multiplying input data D100 and the generator matrix.

According to the present embodiment, when a generator matrix is segmented into blocks, a generator matrix is reproduced from the reference vectors of the row blocks and the reference vectors are multiplied by input data.

Row block reference vector storage sections 301-1 to 301-B change an output reference vector according to the count of input data inputted from input data counting section 101. When the number of times data is inputted is one, the reference vector of the first row block of a generator matrix is outputted.

For example, in the case of G in equation 39, first row block reference vector storage section 301-1 outputs the reference vector of G₁₁, and second row block reference vector storage section 301-2 outputs the reference vector of G₂₁. When the scale of a block is equivalent to an L×L matrix, afterwards, a reference vector to be outputted is switched to the reference vector of the right block every time L bits of input data is received as input.

For example, in G of equation 39, when L bits of input data is received as input, row block reference vector storage section 301-1 switches the reference vector of the G₁₁ block, which is currently outputted, to the reference vector of the G₁₂ block. Afterwards, the block is switched every time L bits of input data is received as input, and, if L bits of input data is received as input while the reference vector of the rightmost column block is outputted, the block is switched to the leftmost column block.

For example, in G of equation 39, if L bits of input data is received as input while first row block reference vector storage section 301-1 currently outputs the reference vector of block G₁₄, a reference vector to be outputted is switched to the reference vector of block G₁₁.

Cyclic shift sections 302-1 to 302-B cyclically shift the reference vectors inputted from row block reference vector storage sections 301-1 to 301-B, according to the count of input data inputted from input data counting section 101.

For example, when the number of times data is inputted is one, a reference vector is subject to a zero-bit cyclic shift and outputted. Afterwards, the number of bits for a cyclic shift is increased by one every time one bit of input data is inputted. When L bits of input data is inputted, blocks for the reference vectors outputted from row block reference vector storage sections 301-1 to 301-B are switched, and, consequently, the amount of cyclic shifts is set zero bit again. Afterwards, similarly, the amount of cyclic shifts is increased by one bit every time one bit of input data is received as input, and the amount of cyclic shifts is returned to zero bit every time the block for the reference vector are changed. By this means, vectors by which input data is multiplied are the same as the vectors of the generator matrix.

Vector cumulative addition sections 304-1 to 304-B reset the cumulative sum vector when the count of input data inputted from input data counting section 101 is zero, and, afterwards, cumulatively adds the vectors inputted from vector multiplying sections 303-1 to 303-B. Vector cumulative addition sections 304-1 to 304-B output to storage section 109 cumulative sum vector as parity data when the number of bits equal to the number of columns in the generator matrix, that is, (N−K) of bits is inputted.

By employing the above-described configuration, it is possible to reduce the circuit scale for reproducing a generator matrix and perform processing for coding in parallel, thereby enabling fast coding.

### Embodiment 4

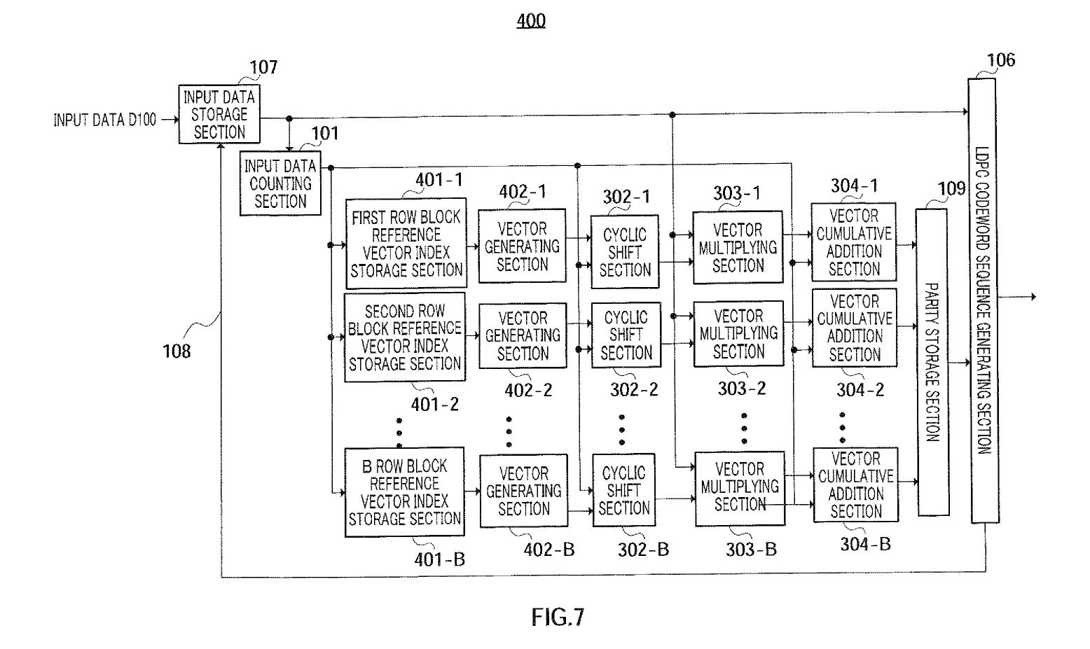

FIG. 7 shows a configuration example of coding apparatus 400 according to Embodiment 4 of the present invention. Further, in Embodiment 4, the same components as in Embodiments 1 to 3 will be assigned the same reference numerals (including terminology) and overlapping explanations will be omitted adequately.

According to the present embodiment, LDPC coding is performed by multiplying a generator matrix and input data and generating parity data. The present embodiment is similar to Embodiment 3 in the approach of reproducing the generator matrix using reference vectors of the row blocks in the generator matrix in cyclic shift sections 302-1 to 302-B, and multiplying the generator matrix and input data. The present embodiment is different from Embodiment 3 in a generation method of the reference vectors of the row blocks in the generator matrix.

According to Embodiment 3, row block reference vector storage sections 301-1 to 301-B hold reference vectors of the row blocks in the generator matrix and use the reference vectors in multiplication. By contrast, according to the present embodiment, reference vector indices are held in the apparatus to generate the reference vectors of the row blocks in the generator matrix, and the indices are used to reproduce the reference vectors. Here, the indices of a reference vector are values showing positions where “1” are in the reference vector.

For example, when a reference vector is [0, 1, 0, 0, 1, 0, 1]^{T}, the indices of the reference vector is [2, 5, 7].

When the reference vector length is L, the number of “1” in the reference vector is Nᵣ and the relationship in equation 40 holds, by generating reference vectors in the process of the present embodiment instead of generating reference vectors in the process of Embodiment 3, it is possible to make the scale of storage sections in coding apparatus 400 smaller.

(Equation 40)

Nᵣ log₂L<L [40]

As described above, coding apparatus 400 of the present embodiment can reduce the circuit scale for reproducing a generator matrix for LDPC codes in the apparatus and perform processing for coding inparallel, thereby enabling fast coding.

The present embodiment will be explained below using a drawing. Unlike Embodiments 1 to 3, coding apparatus 400 in FIG. 7 has row block reference vector index storage sections 401-1 to 401-B and vector generating sections 402-1 to 402-B. According to the present embodiment, sections 101, 401, 402 and 302 to 304 are collectively referred to as a parity generating section. Further, the parity generating section and sections 106 and 109 are collectively referred to as a codeword generating section.

Next, the function of the sections of coding apparatus 400 in FIG. 7 will be briefly explained. Row block reference vector index storage sections 401-1 to 401-B store reference vector indices of row blocks in a generator matrix for performing LDPC coding. The generator matrix used in the present embodiment is a generator matrix calculated from a QC (Quasi Cyclic) quasi lower triangular check matrix.

Vector generating sections 402-1 to 402-B reproduce reference vectors using the indices outputted from the above-noted block reference vector index storage sections. For example, when reference vector indices are [2, 5, 7], the reference vector to be reproduced in a vector generating section is [0, 1, 0, 0, 1, 0, 1]^{T}.

The present embodiment will be explained below in detail. Coding apparatus 400 used in the present embodiment is similar to Embodiment 3 in the multiplication processing for a generator matrix and input data.

According to the present embodiment, when input data is inputted in coding apparatus 400, the input data is held in input data storage section 107. The data held in input data storage section 107 is outputted according to output control signal 108 outputted from LDPC codeword sequence generating section 106. According to the number of input data counted in input data counting section 101, row block reference vector index storage sections 401-1 to 401-B output row block reference vector indices.

For example, first row block reference vector index storage section 401-1 holds the reference vector indices of the first row blocks in the generator matrix. Afterwards, similarly, X-th row block reference vector index storage section 401-X holds the reference vector indices of the X-th row blocks in the generator matrix.

In row block reference vector index storage sections 401-1 to 401-B, indices are outputted according to the account of input data, which means, for example, when the count of input data is one, the reference vector indices of the blocks in the leftmost column in the generator matrix are outputted.

When a block is an L×L matrix, every time L bits of input data is inputted in the apparatus, row block reference vector index storage sections 401-1 to 401-B switch blocks associated with the indices to be outputted, to the right column blocks. When blocks associated with the indices to be outputted are the rightmost column blocks, furthermore, if L bits of input data is inputted row block reference vector index storage sections 401-1 to 401-B switch the reference vector indices to be outputted, to the indices of the leftmost column blocks again.

Vector generating sections 402-1 to 402-B generate reference vectors using the indices outputted from row block reference vector index storage sections 401-1 to 401-B. Afterwards, multiplication of input data and generator matrix is the same as in Embodiment 3.

By this means, it is possible to reduce the circuit scale of coding apparatus 400 and perform fast coding.

### Embodiment 5

Unlike Embodiments 1 to 4 for inputting input data of one-bit width, the coding apparatus according to Embodiment 5 receives input data of two-bit width or more. However, assume that the bit width of input data is a divisor of the number of columns in blocks (i.e., L in FIG. 3) in a generator matrix. Further, the same generator matrix in Embodiments 3 and 4 is used as the generator matrix exemplified in the present embodiment.

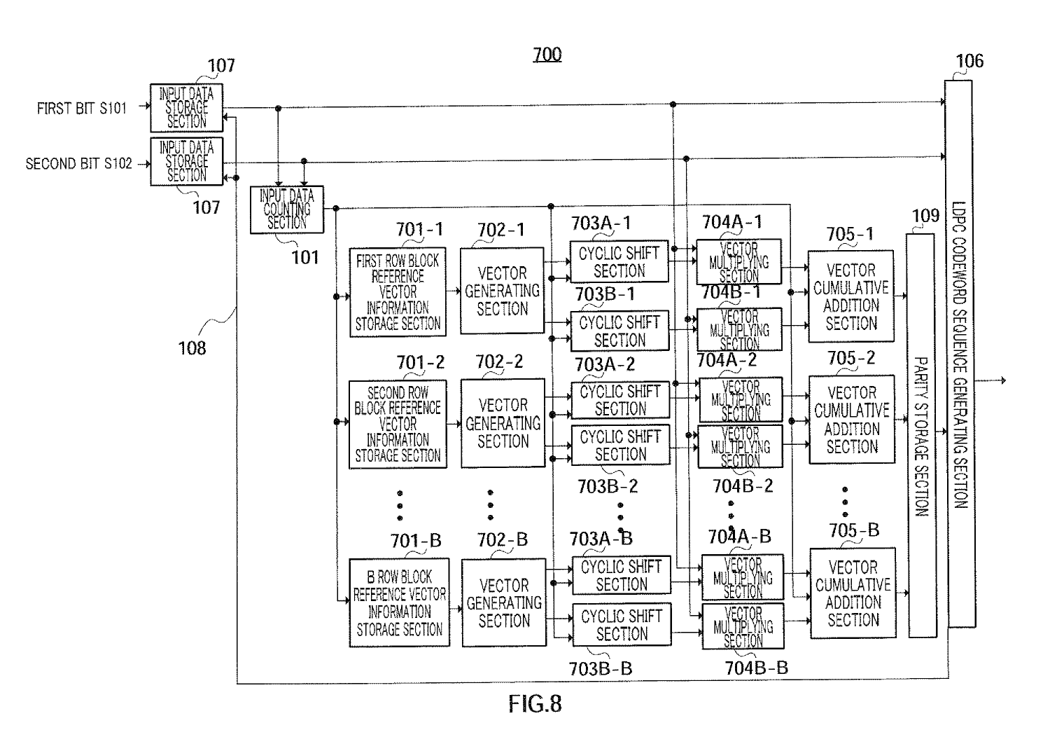

FIG. 8 shows a configuration example of coding apparatus 700 according to Embodiment 5 of the present invention. Further, in Embodiment 5, the same components as in Embodiments 1 to 4 will be assigned the same reference numerals (including terminology) and overlapping explanations will be omitted adequately.

The input data in FIG. 8 has a two-bit width, and, consequently, is comprised of first bit S101 and second bit S102. In the present embodiment, assume that first bit S101 corresponds to the first bit of the input bit sequence of input data D100, and second bit S102 corresponds to the second bit of the input bit sequence of input data D100. Further, the number of bits of input data D100 can apply three or more.

In the present embodiment, sections 701-1 to 701-B, 702-1 to 702-B, 703A-1 to 703A-B, 703B-1 to 703B-B, 704A-1 to 704A-B, 704B-1 to 704B-B and 705-1 to 705-B of coding apparatus 700 in FIG. 8 are equivalent to a multiplication processing section for input data and blocks.

Further, in the present embodiment, vector generating sections 702-1 to 702-B, cyclic shift sections 703A-1 to 703B-B, vector multiplying sections 704A-1 to 704B-B and vector cumulative addition sections 705-1 to 705-B are also referred to as vector generating sections 702, cyclic shift sections 703, vector multiplying sections 704, and cumulative addition sections 705, respectively.

The present embodiment will be explained below in detail using a drawing. In the present embodiment, when input data is two bits or more, reference vectors vary according to the bits. For example, when the bit sequence of input data D100 of the present embodiment is sₜ=[s₀(t) s₁(t)]^{T} and a block of the generator matrix is G_{B}, multiplication of Sₜ and G_{B} is as shown in equation 41.

$$\begin{matrix}( Equation 41 ) & \\ \begin{matrix}{G}_{B} {s}_{t} = [ \begin{matrix}0 & 0 & 1 & 0 & 0 & 1 \\ 1 & 0 & 0 & 1 & 0 & 0 \\ 0 & 1 & 0 & 0 & 1 & 0 \\ 0 & 0 & 1 & 0 & 0 & 1 \\ 1 & 0 & 0 & 1 & 0 & 0 \\ 0 & 1 & 0 & 0 & 1 & 0\end{matrix} ] [ \begin{matrix}{s}_{0} ( 0 ) \\ {s}_{1} ( 0 ) \\ {s}_{0} ( 1 ) \\ {s}_{1} ( 1 ) \\ {s}_{0} ( 2 ) \\ {s}_{1} ( 2 )\end{matrix} ] \\ = [ \begin{matrix}0 \\ 1 \\ 0 \\ 0 \\ 1 \\ 0\end{matrix} ] {s}_{0} ( 0 ) + [ \begin{matrix}0 \\ 0 \\ 1 \\ 0 \\ 0 \\ 1\end{matrix} ] {s}_{1} ( 0 ) + [ \begin{matrix}1 \\ 0 \\ 0 \\ 1 \\ 0 \\ 0\end{matrix} ] {s}_{0} ( 1 ) + [ \begin{matrix}0 \\ 1 \\ 0 \\ 0 \\ 1 \\ 0\end{matrix} ] {s}_{1} ( 1 ) + \\ [ \begin{matrix}0 \\ 0 \\ 1 \\ 0 \\ 0 \\ 1\end{matrix} ] {s}_{0} ( 2 ) + [ \begin{matrix}1 \\ 0 \\ 0 \\ 1 \\ 0 \\ 0\end{matrix} ] {s}_{1} ( 2 )\end{matrix} & [ 41 ]\end{matrix}$$

In equation 41, when t=0 changes to t=1, it is clear that the vector multiplied by S₀(1) is a vector subject to a two-bit cyclic shift of the vector multiplied by S₀(0).

Further, it is clear that the vector multiplied by which s₁(1) is multiplied is a vector subject to a two-bit cyclic shift of the vector by which s₁(0) is multiplied. Further, it is clear from equation 41 that the reference vector multiplied by s₁(0) in t=0 can be generated by a one-bit cyclic shift of the reference vector multiplied by s₀(0).

Therefore, according to the present embodiment, the reference vector of the block (i.e., the leftmost column vector of the block) associated with first bit S101 in the generator matrix is stored in the coding apparatus in advance. The reference vector associated with second bit S102 is generated by a one-bit cyclic shift of the reference vector associated with first bit S101. For example, the above-noted reference vector multiplied by S₀(0) in t=0 is stored in the coding apparatus in advance, and the reference vector associated with S₁(0) is generated by a one-bit cyclic shift of the reference vector associated with S₀(0).

Further, after the reference vector is generated (for example, after t=1), by multiplying input data and vectors acquired by two-bit cyclically shifting the generated vector sequentially, and cumulatively adding the output reference vectors, multiplication of the generator matrix and input data is performed. When the block of the generator matrix is shifted, as in the above-noted case of t=0, the reference vector associated with the shifted block is generated and sequentially multiplied with input data. By using the cumulative sum as a parity bit at the time the input data and rightmost vector of the generator matrix are multiplied, and generating an LDPC code sequence from the input data and parity bit, it is possible to realize coding.

Unlike Embodiment 1, coding apparatus 700 in FIG. 8 has row block reference vector information storage sections 701-1 to 701-B, vector generating sections 702-1 to 702-B, two-bit cyclic shift sections 703A-1 to 703A-B and 703B-1 to 703B-B, vector multiplying sections 704-A-1 to 704A-B and 704B-1 to 704B-B, and vector cumulative addition sections 705-1 to 705-B.

Further, in the present embodiment, sections 101 and 701-1 to 701-B, 702-1 to 702-B, 703A-1 to 703A-B, 703B-1 to 703B-B, 704A-1 to 704A-B, 704B-1 to 704B-B, and 705-1 to 705-B are collectively referred to as a parity generating section. Further, a combination of the parity generating section and sections 109 and 106 is referred to as an LDPC codeword generating section.

Input data counting section 101 counts the sum of the numbers of times first bit S101 and second bit S102 are inputted, and outputs the result.

Row block reference vector information storage sections 701-1 to 701-B store reference vector information of the row blocks in the generator matrix. For example, the reference vectors can be stored as is like Embodiment 3, or index information can be stored like Embodiment 4. As in Embodiments 3 and 4, row block reference vector information storage sections 701-1 to 701-B output reference vector information according to the count of input data.

Vector generating sections 702 generate the reference vectors of the blocks according to the reference vector information acquired from row block reference vector information storage section 701. In this case, when the reference vector information is the reference vector as is, vector generating sections 702 output the reference vectors. On the other hand, when the reference vector information is index information, vector generating sections 702 need to generate vectors where elements “1” are in the parts associated with the indices. Vector generating sections 702 output all the above-noted reference vectors to the two-bit cyclic shift sections in the direction of A (see code A in FIG. 8) (also called A system).

Vector generating sections 702 output vectors one-bit cyclically shifting the vectors outputted to bit cyclic shift sections in the A system, to two-bit cyclic shift sections in the direction of B (also called B system).

Two-bit cyclic shift sections 703 cyclic shift the reference vectors inputted from vector generating sections 702-1 to 702-B, according to the count of input data inputted from input data counting section 101.

For example, when the number of input data is one, the reference vectors are subject to a zero-bit cyclic shift and outputted. Afterwards, every time two bits of input data is inputted in the apparatus, the number of bits for a cyclic shift is increased by two. When L bits are inputted, the blocks of the reference vectors outputted from the row block reference vectors storage sections are switched, and, consequently, the amount of cyclic shifts is set zero bit again. Afterwards, the amount of cyclic shifts is increased by two bits every two bits of input data is inputted in the apparatus, and the amount of cyclic shifts is returned to zero bit every time blocks of the reference vectors are switched. By this means, vectors by which input data is multiplied are the same as the vectors in the generator matrix.

Further, a two-bit cyclic shift is performed since vectors multiplied by first bit S101 are equivalent to vectors acquired by a two-bit cyclic shift of the reference vectors sequentially. For example, in equation 20, when t=0 changes to t=1, the vector multiplied by s₀(1) is equivalent to a vector subject to a two-bit cyclic shift of the reference vector associated with s₀(0).

Vector multiplying sections 704A-1 to 704A-B and 704B-1 to 704B-B calculate the vector multiplication of the output values outputted from cyclic shift sections 703 and first bit S101 and vector multiplication of the output values and second bit S102, and output the multiplication results to vector cumulative addition sections 705-1 to 705-B.

Vector cumulative addition sections 705-1 to 705-B control the vector cumulative sum according to the output from input data counting section 101. When the count number of input data is zero, vector cumulative addition sections 705 reset the cumulative sum vector. When the count of input data is not zero, the outputs from vector multiplying sections 704 are cumulatively added.

When all the input data are inputted, that is, when (N−K) bits of input data is inputted, vector cumulative addition sections 705 output the vector cumulative addition values as parities.

Afterwards, as in Embodiments 3 and 4, LDPC codeword sequence generating section 106 rearranges input data and parity data, and generates and outputs an LDPC codeword.

As described above, coding apparatus 700 according to Embodiment 5 can perform parallel processing with respect to input data of a plurality of bits and generate parity bits, and generate an LDPC codeword.

### Embodiment 6

Generally, when bits less than the number of columns in the generator matrix, that is, bits less than (N−K) of a bit sequence is inputted as input data, a step of inserting “0” in the end of the bit sequence of the input data to match the number of columns (N−K) in the generator matrix, and a step of performing linear calculations of the inserted “0” and the generator matrix, are needed.

When bits less than the number of columns in the generator matrix, that is, bits less than (N−K) of a bit sequence is inputted as input data, by outputting, as parities, linear calculation results of input data that is all inputted in the apparatus and the generator matrix, coding apparatus 800 according to Embodiment 6 has a feature of eliminating the above-described steps of inserting “0” and performing linear calculations of the inserted “0” and generator matrix. The present embodiment will be explained below in detail using a drawing.

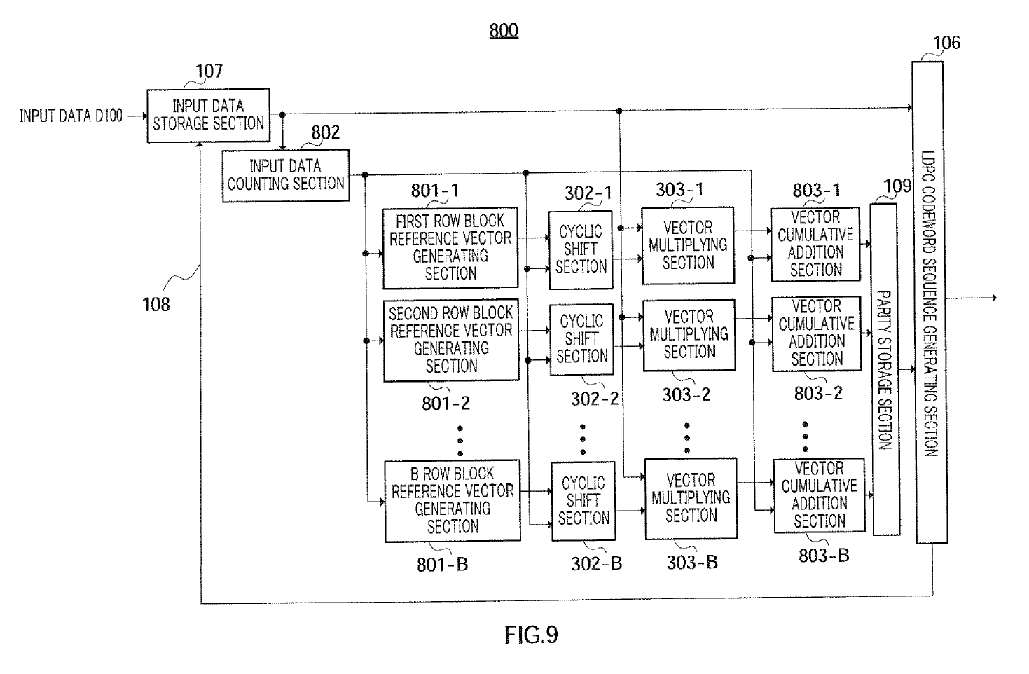

FIG. 9 shows a configuration example of coding apparatus 800 according to Embodiment 6 of the present invention. Further, in Embodiment 6, the same components as in Embodiments 1 to 3 will be assigned the same reference numerals (including terminology) and overlapping explanations will be omitted adequately.

Unlike Embodiments 1 to 3, coding apparatus 800 in FIG. 9 has input data counting section 802, row block reference vector generating sections 801-1 to 801-B, and vector cumulative addition sections 803-1 to 803-B. Input data counting section 802 counts the number of times data is inputted in coding apparatus 800, and, when input data is all received as input, outputs a control signal showing that the input data is all inputted, to cumulative addition sections 803-1 to 803-B.

Row block reference vector generating sections 801 have a function combining row block reference vector information storage section 701 and vector generating section 702 of coding apparatus 700 in FIG. 8, and output the reference vectors of blocks according to the count of inputs.

Vector cumulative addition sections 803 perform processing of cumulative addition calculations according to the output from input data counting section 802. Vector cumulative calculation sections 803 reset the cumulative sum vector when the number of times data is inputted in coding apparatus 800 is zero. By contrast, afterwards, vector cumulative addition sections 803 cumulatively add the output vectors from vector multiplying sections 303 when the number of times data is inputted is not zero. In this case, upon acquiring from input data counting section 802 the control signal showing that input data is all inputted in coding apparatus 800, vector cumulative addition sections 803 finishes the cumulative addition and output the cumulative sum vector at that time, as parity data. The following processing in the LDPC codeword generating section is the same as in Embodiments 3 and 4.

According to the present embodiment, it is not necessary to insert “0” in the end of input data D100 of bits less than the number of columns (N−K) in the generator matrix and perform a series of processing. Therefore, it is possible to reduce delay time before parity bits are outputted.

### Embodiment 7

The coding apparatus according to Embodiment 7 relates to sharing a parity generating section in a plurality of different modes (i.e., different code length and coding rates). Here, the parity generating section is the same as the parity generating section described in Embodiments 1 to 6.

For example, when parity bits are generated in two different modes (i.e., the first mode and second mode), the number of blocks in the generator matrix and the block length vary according to the modes. Here, the block length shows the scale of the blocks and can be defined by the scale of a matrix such as 27×27.

To be more specific, for example, when the code length is 648, the coding rate is ½ and the block length is 27×27 in the first mode, the generator matrix associated with the first mode (i.e., the generator matrix acquired from the check matrix in equation 10) is formed with twelve row blocks and twelve column blocks. On the other hand, when the code length is 1944, the coding rate is ¾ and the block length is 81×81 in the second mode, the generator matrix associated with the second mode is formed with six row blocks and eighteen column blocks.

In this case, the block length is different between the first mode and the second mode. Consequently, although sharing the cyclic shift section, vector multiplying section and vector cumulative addition section in the parity generating section cannot be performed, when the coding length is 648, the coding rate is ¾ and block length is 27×27 in, for example, the third mode, the generator matrix is formed with six row blocks and eighteen column blocks. In this case, between the first mode and the third mode, it is possible to share the cyclic shift section, vector multiplying section and vector cumulative addition section in the parity generating section. Therefore, a feature of the present embodiment lies in sharing the coding apparatus when there are two or more different modes. However, according to the present embodiment, the scale of the coding apparatus is controlled by the mode having the largest number of row blocks amongst the number of row blocks in each mode. For example, the first mode has twelve row blocks and twelve column blocks and the third mode has six row blocks and eighteen column blocks, and the coding apparatus requires cyclic shift sections, vector multiplying sections and vector cumulative addition sections for twelve row blocks.

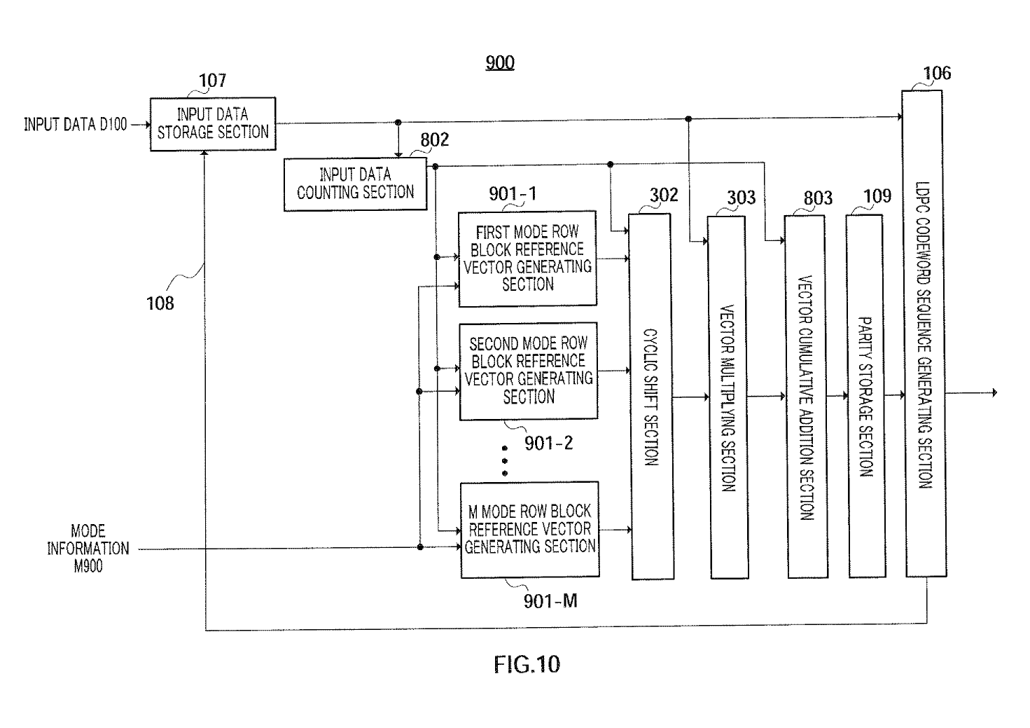

FIG. 10 shows a configuration example of coding apparatus 900 according to Embodiment 7. An example case will be described with the present embodiment where the number of modes performing coding at the same time is M. Further, in Embodiment 7, the same components as in Embodiments 1 to 6 will be assigned the same reference numerals (including terminology) and overlapping explanations will be omitted adequately.

In FIG. 10, unlike Embodiments 1 to 6, coding apparatus 900 has mode row block reference vector generating sections (or mode row reference generating sections) 901-1 to 901-M. Mode block reference vector generating sections hold the reference vectors of row blocks in generator matrices associated with respective modes.

Further, in the present embodiment, mode block reference vector generating sections 901-1 to 901-M can be expressed as mode row block reference vector generating sections 901.

Mode row block reference vector generating sections 901 output the reference vectors held in mode row block reference vector generating sections 901 upon receiving as input associated mode information M900. A generation method of reference vectors is the same as in Embodiment 6.

Afterwards, cyclic shift section 302, vector multiplying section 303 and vector cumulative addition section 803 generate parity data using the reference vectors associated with the mode for coding outputted from mode row block reference vector generating sections 901-1 to 901-M. The generation of parity data is the same as in Embodiments 3 to 6.

Further, the generated parity data is stored in parity storage section 109, and parity data generated in LDPC codeword sequence generating section 106 and input data are rearranged and subjected to coding processing.

By employing the above-noted configuration, coding apparatus 900 according to the present embodiment can share the cyclic shift section, vector multiplying section and vector multiplying section in a plurality of different modes. As described above, it is possible to reduce the circuit scale of a coding apparatus in a communication system where there are a plurality of modes.

### Embodiment 8

A case will be shown with the present embodiment where the coding apparatus according to Embodiments 1 to 7 is used to form a radio transmitting apparatus (or radio apparatus)

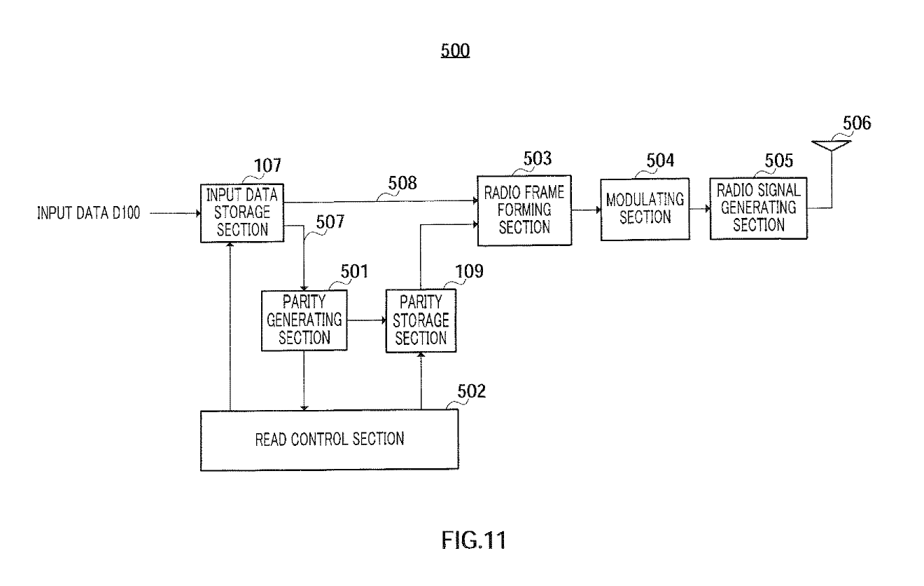

FIG. 11 shows a configuration example of radio transmitting apparatus 500 according to Embodiment 8 of the present invention. Further, in Embodiment 8, the same components as in Embodiment 1 will be assigned the same reference numerals (including terminology) and overlapping explanations will be omitted adequately.

According to the present embodiment, the coding apparatus described in Embodiments 1 to 7 is used to form a radio transmitting apparatus. That is, the radio transmitting apparatus utilizes a configuration in which, before input data is inputted in a parity generating section, the input data is held in an input data storage section. Further, the radio transmitting apparatus utilizes a configuration in which output parity from the parity generating section is held in the parity storage section. A feature of the present embodiment lies in performing interleaving processing in radio transmission by controlling reading patterns from the input data storage section and parity storage section.

Interleaving processing will be explained below. Interleaving refers to a technique of randomizing burst errors (indicating consecutive errors in information data) of radio signals caused in the receiving apparatus by radio signals distorted by fading fluctuation in radio transmission channels.

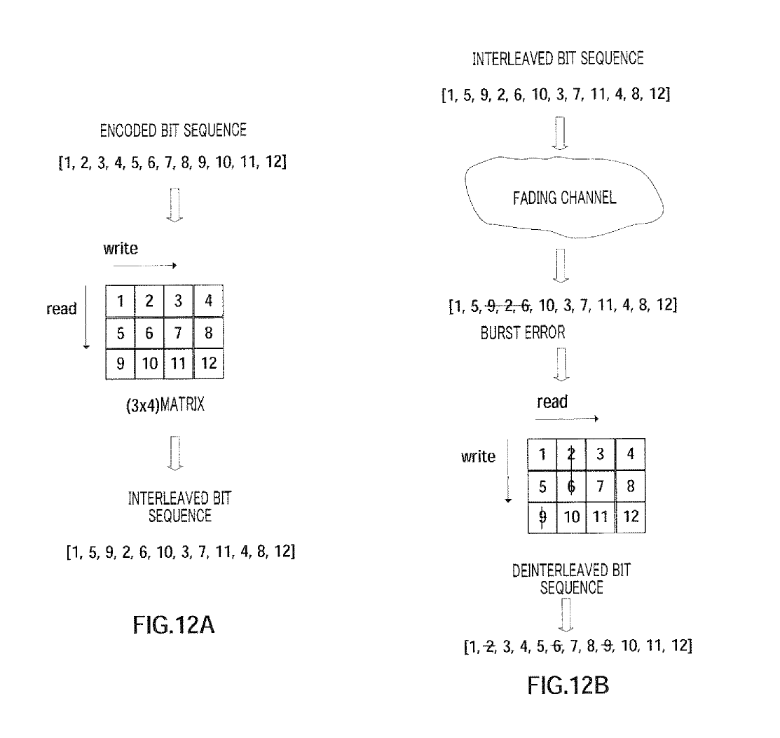

To perform interleaving processing, for example, as shown in FIG. 12A, an encoded bit sequence (i.e., a bit sequence after LDPC coding in the present embodiment) is stored in a 3×4 matrix. Here, in writing in the matrix, the encoded bit sequence is written in the write direction shown in FIG. 12A in order. Next, in reading, reading is performed in the read direction. By this means, the receiving apparatus can randomize errors caused by fading.

For example, as shown in FIG. 12B, assume that, in the receiving apparatus, burst errors occur in part (slash parts) of the bit sequence due to distortion caused by the interleaved bit sequence passing fading transmission channels. In this case, similar to the transmitting apparatus, the received codeword sequence is written in a 3×4 matrix and read adequately. Here, the write direction and read direction are different from the transmitting apparatus.

In FIG. 12B, as in FIG. 12A, by performing writing in the write direction and performing reading in the read direction, it is possible to rearrange an encoded bit sequence in the correct order in the receiving apparatus (not shown). In this case, it is clear that parts of burst errors in the receiving apparatus are randomized.

As described above, it is possible to randomize burst errors in the receiving apparatus by performing interleaving processing. Further, the interleaving technique is disclosed in further detail in references such as Non-Patent Document 3.

The present embodiment will be explained below in detail using drawings. Radio transmitting apparatus 500 in FIG. 11 is provided with input data storage section 107, parity generating section 501, read control section 502, parity storage section 109, radio frame forming section 503, modulating section 504, radio signal generating section 505 and radio signal transmitting section 506.

Next, the function of the sections of radio transmitting apparatus 500 in FIG. 11 will be briefly explained. As in Embodiment 1, input data storage section 107 has a holding function. However, input data storage section 107 according to the present embodiment further performs reading according to a control signal from read control section 502.

Parity generating section 501 has the same function as in the generating section of Embodiments 1 to 7. That is, upon receiving input data D100, parity generating section 501 outputs parity data associated with input data D100.

As Embodiment 1, parity storage section 109 has a function for holding parity data. However, parity storage section 109 according to the present embodiment further performs reading according to a control signal from read control section 502.

Read control section 502 outputs a control signal such that the input data held in input data storage section 107 is read according to an interleaving pattern. When the input data has been readout, read control section 502 then outputs a control signal such that parity data is read out according to the interleaving pattern.

Radio frame forming section 503 attaches header information and such, needed to form a radio frame, to the encoded bit sequence. Modulating section 504 modulates the radio frame by a known modulation scheme used in a communication system.

Radio signal generating section 505 performs up-conversion of the modulated signal to a radio transmission frequency band used in the communication system. Radio signal transmitting section 506 transmits the above-noted signal after up-conversion.

The present embodiment will be explained below in detail. In radio transmitting apparatus 500 in FIG. 11, input data storage section 107 holds input data D100. Next, read control section 502 controls input data held in input data storage section 107 to be read out, as data 507, in parity generating section 501 side in the order the input data was inputted in radio transmitting apparatus 500.

Parity generating section 501 generates parities from data 507 read out from input data storage section 107 and outputs parity data to parity storage section 109.

Upon finishing generating parities associated with the input data sequence, parity generating section 501 outputs a control signal showing the fact that the parities were generated, to read control section 502. In this case, read control section 502 outputs the control signal such that reading is performed for input data storage section 107 according to the interleaving pattern used in radio transmitting apparatus 500.

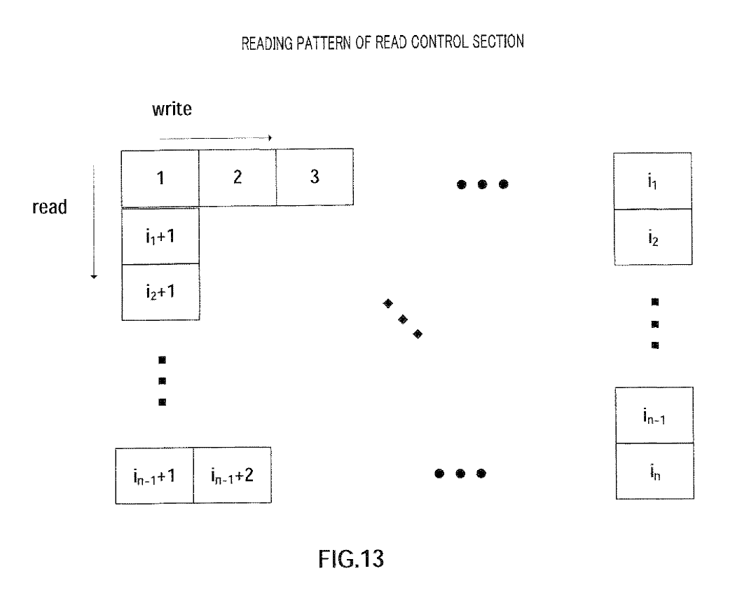

To be more specific, as shown in the read pattern in FIG. 13, read control section 502 prepares, virtually, a table writing the data stored in input data storage section 107 and parity data stored in parity storage section 109 in the write direction.

In this table, read control section 502 outputs a control signal to input data storage section 107 and parity storage section 109 such that reading is performed in the read direction.

Input data storage section 107 and parity storage section 109 perform reading according to the above-noted control signal. By the above-described method, it is possible to perform interleaving processing.

Radio frame forming section 503 attaches header information and such, needed for a radio frame, to the data outputted from input data storage section 107 and parity storage section 109, and outputs the result.

Modulating section 504 modulates the output from radio frame forming section 503 using a known modulation scheme in a communication system, and outputs the result.

Radio signal generating section 505 performs up-conversion of the above-described modulated signal to a radio frequency band in the communication system. Radio signal transmitting section 506 outputs the above-described signal after up-conversion. By employing the above-noted configuration, it is possible to perform interleaving processing in radio transmission.

### Embodiment 9

A case will be described with the present embodiment where the radio transmitting apparatus and radio receiving apparatus (radio apparatus) used in Embodiments 1 to 7 are configured.

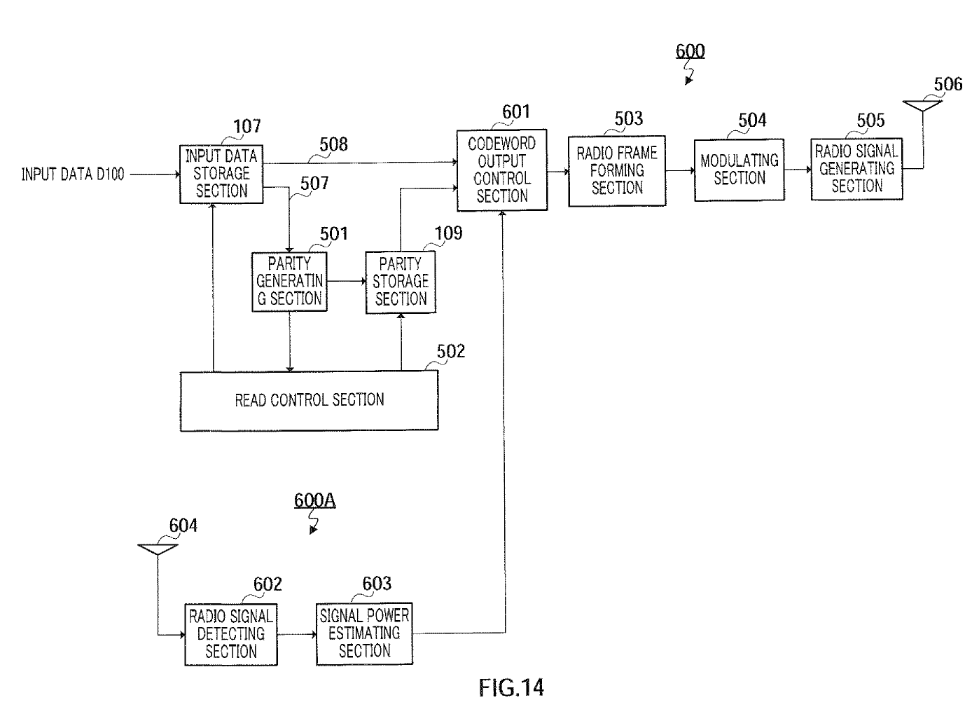

FIG. 14 shows a configuration example of radio transmitting apparatus 600 and radio receiving apparatus 600A according to Embodiment 9 of the present invention. Further, in Embodiment 9, the same components as in Embodiments 1 to 8 will be assigned the same reference numerals (including terminology) and overlapping explanations will be omitted adequately.

Radio transmitting apparatus 600 of the present embodiment is configured using the coding apparatus in Embodiments 1 to 7. To be more specific, radio transmitting apparatus 600 performs puncturing processing to change the coding rate of a generated codeword. Further, radio transmitting apparatus 600 uses adaptive modulation in a known communication system.

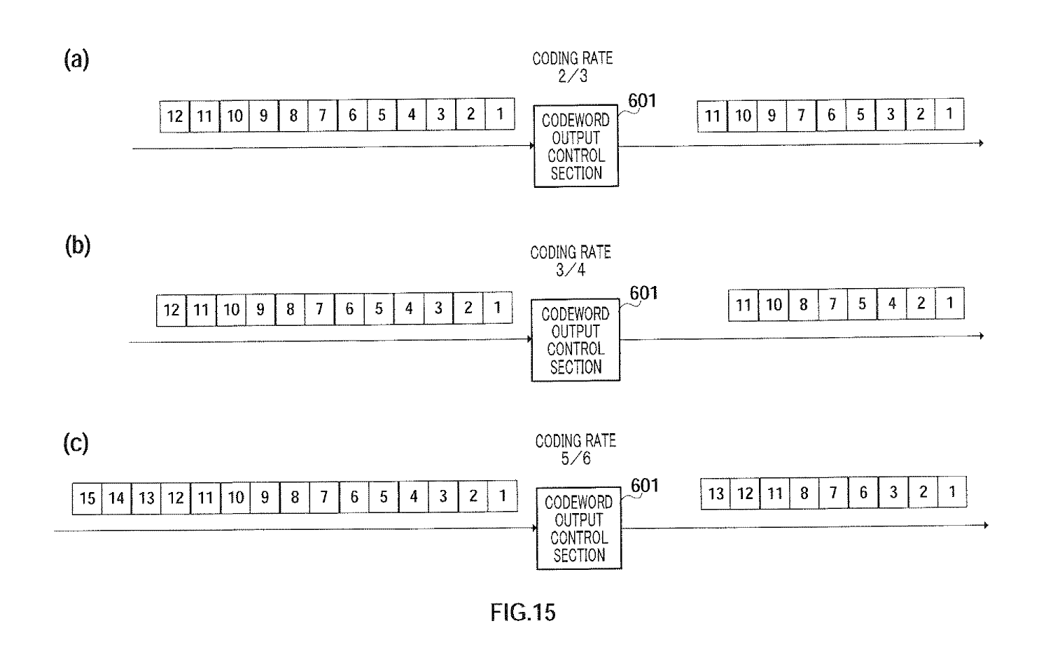

Here, the puncturing processing refers to processing of changing the coding rate by puncturing the output of a codeword. This is exemplified in FIG. 15. For example, as shown in FIG. 15(a), when the coding rate of an LDPC code is ⅔, codeword output control section 601 punctures one bit every four bits, and generates and outputs a codeword of the coding rate of ⅔.

Further, as shown in FIG. 15(b), a codeword of a coding rate of ¾ is generated by puncturing one bit every three bits.

Further, as shown in FIG. 15(c), a codeword of a coding rate of ⅚ is generated by puncturing two bits every five bits.

Further, adaptive modulation refers to a scheme of changing the coding rate in the transmitting apparatus according to the information signal to noise power ratio (“SNR”) of a received signal in the receiving apparatus. In a case of a communication system in which a coding rate is not fixed, generally, a generator matrix matching the coding rate is necessary to generate a codeword. However, a feature of radio receiving apparatus 600 of the present embodiment lies in generating codewords of different coding rates by performing puncturing processing for a codeword to be outputted.

The present embodiment will be explained below using drawings. Unlike Embodiment 8, radio transmitting apparatus 600 in FIG. 14 has codeword output control section 601.

Furthermore, radio receiving apparatus 600A further has radio receiving section 604, radio detecting section 602 and signal power estimating section 603 in addition to radio transmitting apparatus 600.

Codeword output control section 601 selects and outputs transmission data from a generated LDPC codeword of a given coding rate (e.g., 1/2), such that a desirable coding rate is given. This processing is equivalent to the above-noted puncturing processing.

Further, an example case of puncturing processing has been described above where a codeword of another coding rate is generated from a codeword of a coding rate of ½. However, actually, the coding rate of a source codeword is not especially designated. The other components of radio transmitting apparatus 600 are the same as radio transmitting apparatus 500 in Embodiment 8.

Next, the function of the sections of radio receiving apparatus 600A will be explained. Radio receiving apparatus 600A outputs a radio signal received in radio receiving section 604, to radio signal detecting section 602. Radio signal detecting section 602 detects the received signal (radio signal) from radio receiving section 604. Although the method of detection is not specified according to the present embodiment, there is a method of detecting radio signals using, for example, synchronization detection.

Signal power estimating section 603 receives the detected output and estimates the power and noise power of the information signal. By this means, an estimation value of the SNR is found, and the coding rate of the radio frame to be transmitted next is determined in receiving apparatus 600A (signal power estimating section 603). Further, signal estimating section 603 in radio receiving apparatus 600A feeds back the coding rate to codeword output control section 601 of transmitting apparatus 600.

After that, puncturing processing is performed in codeword output control section 601 such that the coding rate fed back from receiving apparatus 600A is found, and a codeword of a desirable coding rate is generated.

By employing the above-noted configuration, even in a communication system using adaptive modulation, by holding only one generator matrix in radio transmitting apparatus 600, it is possible to generate codewords of various coding rates.

### Embodiment 10

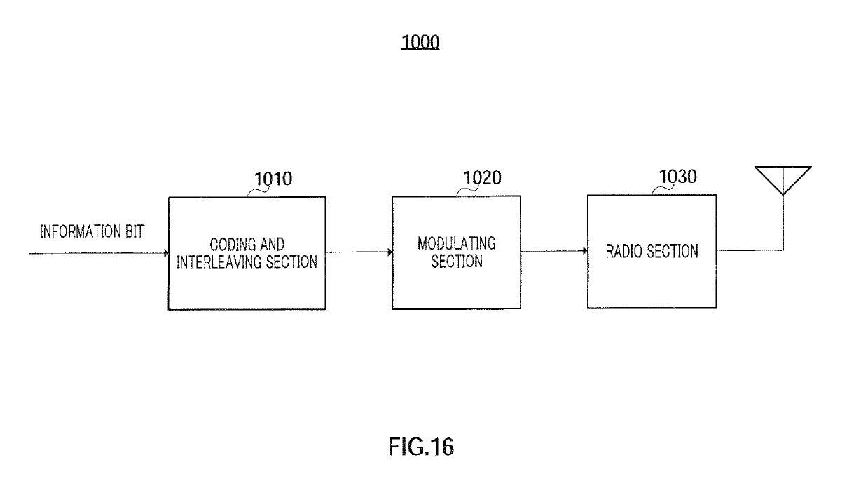

FIG. 16 shows a configuration example of the radio transmitting apparatus according to Embodiment 10 of the present invention. Radio transmitting apparatus 1000 in FIG. 16 is provided with coding and interleaving section 1010, modulating section 1020 and radio section 1030.

In radio transmitting apparatus 1000 in FIG. 16, information bits are inputted in coding and interleaving section 1010. Coding and interleaving section 1010 performs LDPC coding and interleaving of the information bits. Further, LDPC coding and interleaving will be described later in detail. Coding and interleaving section 1010 outputs the code bits after LDPC coding and interleaving, to modulating section 1020.

Modulating section 1020 modulates the code bits. Here, modulation refers to modulation schemes such as the QPSK (Quadrature Phase Shift Keying) modulation scheme and 16 QAM (Quadrature Amplitude Modulation) modulation scheme. After the modulation, modulating section 1020 outputs the modulation signals to radio section 1030.

Radio section 1030 generates radio signals using the inputted modulation signals. Here, the radio signal refers to, for example, an OFDM (Orthogonal Frequency Division Multiplexing) modulation signal or a signal acquired by performing up-conversion of a single carrier modulation signal, to a radio frequency band. To generate an OFDM modal at ion signal from the inputted modulation signal in radio section 1030, the method disclosed in Non-Patent Document 4 may be used. Radio section 1030 outputs the generated radio signals to radio channels.

Next, LDPC coding and interleaving in coding and interleaving section 1010 will be explained using equations. Interleaving is equivalent to an operation of rearranging the order of coding bits as shown in Embodiment 8. Here, when the interleaving pattern in this case is 11, a series of operations of LDPC coding of information bits and interleaving of coding bits after LDPC coding, can be expressed by equation 42. Further, in equation 42, x represents the interleaved coding bit, G₁ represents the generator matrix for generating an LDPC codeword, and s represents the input information bit.

(Equation 42)

x=πG₁s [42]

G₁ in equation 42 is the generator matrix for generating an LDPC codeword and is comprised of identity matrix I and parity generator matrix G. G₁ is shown in equation 43. Here, G is the parity generator matrix for generating parity bits shown in equation 16.

$$\begin{matrix}( Equation 43 ) & \\ {G}_{l} = [ \begin{matrix}I \\ G\end{matrix} ] & [ 43 ]\end{matrix}$$

According to equation 43, G₁s in equation 42 is G₁s=[I^{T}G^{T}]^{T}s=[s^{T}p^{T}]^{T}, so that it is possible to find an LDPC codeword. The LDPC codeword is interleaved according to interleaving pattern π. To be more specific, by multiplying the LDPC codes by interleaving pattern π, it is possible to realize interleaving. An example case is shown in equation 44 where the LDPC codeword length is three.

$$\begin{matrix}( Equation 44 ) & \\ Π {G}_{l} s = [ \begin{matrix}0 & 0 & 1 \\ 1 & 0 & 0 \\ 0 & 1 & 0\end{matrix} ] [ \begin{matrix}{c}_{0} \\ {c}_{1} \\ {c}_{2}\end{matrix} ] = [ \begin{matrix}{c}_{2} \\ {c}_{0} \\ {c}_{1}\end{matrix} ] & [ 44 ]\end{matrix}$$

In equation 44, [c₀, c₁ c₂]^{T} represents the LDPC codeword, and, by multiplying the LDPC codeword by interleaving pattern π, the LDPC codeword is interleaved, thereby finding [c₂ c₀ c₁]^{T}. Further, interleaving is the operation of rearranging the order of coding bits, and, consequently, notice that there is only one element of “1” in each row in the interleaving pattern.

Thus, by multiplying an LDPC codeword by an interleaving pattern, it is possible to realize interleaving. Here, assume that the interleaving pattern is comprised of cyclic shifts of the identity matrix or zero matrix. That is, a submatrix of an interleaving pattern is a cyclic shift of an identity matrix or is a zero matrix. Further, in this case, the scale of the submatrix of the interleaving pattern and the scale of a submatrix of a parity generator matrix are the same. In this case, according to the relationship in equation 24 shown in this embodiment, the matrix (hereinafter “interleaved matrix”) given by multiplying the interleaving pattern and the generator matrix for an LDPC codeword is also comprised of a sum of cyclic shifts of the identity matrix or zero matrix. Therefore, as shown in equation 45, let the matrix given by multiplying the interleaving pattern and the generator matrix for an LDPC codeword is newly made G_{X}, LDPC coding and the interleaving of the LDPC codeword can be expressed only by multiplication of input information s and G_{X}.

$$\begin{matrix}( Equation 45 ) & \\ \begin{matrix}Π {G}_{l} = [ \begin{matrix}{Π}_{11} & {Π}_{12} \\ {Π}_{21} & {Π}_{22}\end{matrix} ] [ \begin{matrix}I \\ G\end{matrix} ] \\ = [ \begin{matrix}{Π}_{11} + {Π}_{12} G \\ {Π}_{21} + {Π}_{22} G\end{matrix} ] \\ = {G}_{X}\end{matrix} & [ 45 ]\end{matrix}$$

Further, in equation 45, interleaving pattern π is segmented into matrix π₁₁ having the same scale as generator matrix I, matrix π₂₁ having the same scale as generator matrix G, matrix π₁₂ having the same number of rows as identity matrix I and the same number of columns as the number of rows of generator matrix G, and matrix π₂₂ having the same number of rows and columns as the number of rows of generator matrix G, and these division results are described. π₁₁ to π₂₂ are formed including submatrices, which are cyclic shifts (here, these if to π₂₂ do not always represent submatrices).

In this case, by employing the same configuration as the coding apparatus used in Embodiments 1 to 7, it is possible to realize coding and interleaving section 1010 according to the present embodiment. That is, only by employing the same configuration as the coding apparatus used in Embodiments 1 to 7, it is possible to realize interleaving of coding bits after LDPC coding and LDPC coding, thereby reducing the circuit scale of the radio transmitting apparatus.

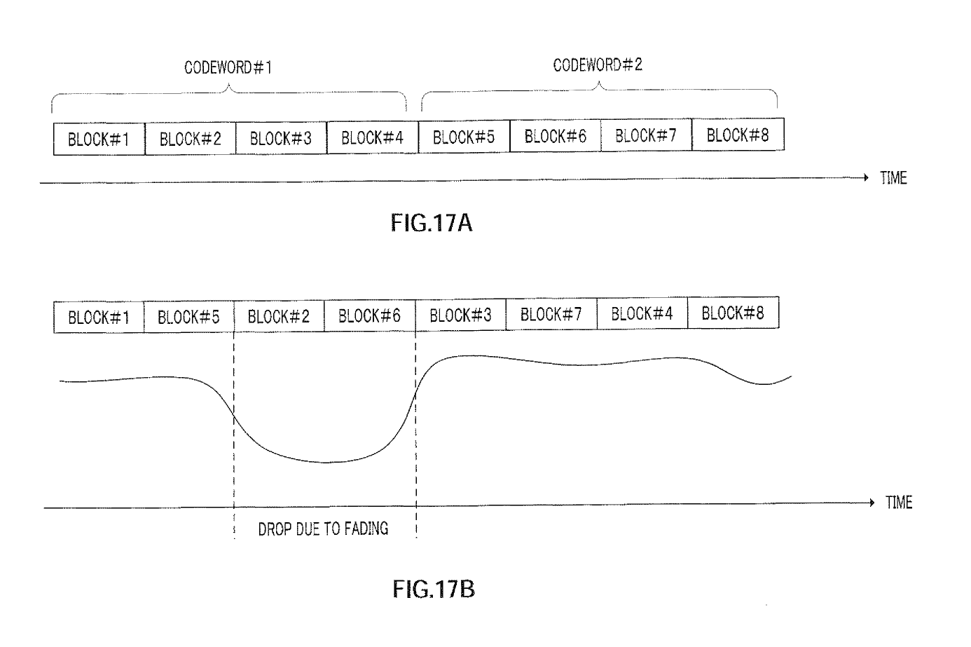

Here, a case has been described with the above-described explanations where interleaving is performed in one LDPC codeword. Therefore, the effect of error coding upon decoding LDPC codes is given in one codeword. For example, as an LDPC codeword sequence, as shown in FIG. 17A, a case will be assumed where codeword #1 and codeword #2 are arranged in order. In this case, only codeword #1 finds the effect of error correction acquired by decoding codeword ##1, and, similarly, only codeword #2 finds the effect of error correction acquired by decoding codeword #2.

A case will be explained below where interleaving is performed for a plurality of LDPC codewords. For example, a case is assumed where interleaving is performed for codeword #1 and codeword #2 and the sequences of codeword #1 and codeword #2 are mixed as shown in FIG. 17B. The scale of the block shown in FIG. 17B is the same as the scale of submatrix that is a sum of cyclic shifts of the identity matrix in matrix G_{X} subjected to LDPC coding and interleaving. That is, a unit of a code bit acquired by multiplication of input information bit s and submatrix, is defined as one block.

In this case, as shown in FIG. 17B, even when, in radio signals transmitted from radio transmitting apparatus 1000 in radio channels, radio signal parts associated with block #2 of codeword #1 and block #6 of codeword #2 are subject to fading and the power of the signals decreases, the influence of fading is dispersed to codeword #1 and codeword #2, so that it is possible to disperse the influence of degradation of error correction upon decoding LPDC codes.

Thus, to perform interleaving over a plurality of LDPC codewords is an effective technique for reducing the influence of degradation of error correction due to fading. Further, even when a modulation signal is generated by OFDM modulation in modulating section 1020, the influence of fading on subcarrier signals can be dispersed to a plurality of LDPC codewords, so that the above-described technique is effective to reduce degradation of error correction due to fading.

In this case, a matrix for coding and interleaving a plurality of LDPC codewords can be expressed as shown in equation 46.

$$\begin{matrix}( Equation 46 ) & \\ Π {G}_{L} = [ \begin{matrix}{Π}_{11} & {Π}_{12} & {Π}_{13} & {Π}_{14} \\ {Π}_{21} & {Π}_{22} & {Π}_{23} & {Π}_{24} \\ {Π}_{31} & {Π}_{32} & {Π}_{33} & {Π}_{34} \\ {Π}_{41} & {Π}_{42} & {Π}_{43} & {Π}_{44}\end{matrix} ] [ \begin{matrix}I \\ {G}_{1} \\ I \\ {G}_{2}\end{matrix} ] & [ 46 ]\end{matrix}$$

In equation 46, G_{L} represents a generator matrix for generating a plurality of LDPC codewords. Further, equation 46 shows that interleaving is performed for two LDPC codewords, and that G₁ represents the parity generator matrix for generating parity bits of the first LDPC code and G₂ represents the parity generator matrix for generating parity bits of the second LDPC code. To perform interleaving of three or more LDPC codewords, generator matrix G_{L} needs to be expanded and further coupled with a generator matrix for generating an LDPC codeword. A generator matrix to be coupled can be the same matrix or a different matrix.

Thus, by multiplying the matrix coupled with the generator matrix for generating LDPC codes by interleaving pattern π, it is possible to realize interleaving of a plurality of LDPC codes. When a submatrix of the interleaving pattern is a cyclic shift of the identity matrix or is a zero matrix, and a submatrix of the generator matrix is a sum of cyclic shifts of the identity matrix, it is possible to realize coding and interleaving over a plurality of LDPC codes. Further, notice that there is only one element of “1” in each row in the interleaving pattern.

Supplemental explanations will be described below about processing coding and interleaving over a plurality of LDPC codes. As shown in FIG. 17, an example case will be described below where LDPC coding and interleaving processing are performed over two codewords #1 and #2, that is, over eight blocks (blocks #1 to #8). As shown in equation 46, if the matrix (interleaved matrix) multiplying a generator matrix for generating an LDPC codeword by an interleaving pattern is G_{B}, when LDPC coding and interleaving processing is performed over the eight blocks, G_{B} can be expressed as shown in equation 47.

$$\begin{matrix}( Equation 47 ) & \\ {G}_{B} = [ \begin{matrix}{G}_{B 1} \\ {G}_{B 2} \\ ⋮ \\ {G}_{B 8}\end{matrix} ] & [ 47 ]\end{matrix}$$

Submatrices G_{B1} G_{B2}, . . . , G_{B8} shown in equation 47 and input information bit s are multiplied to generate blocks in the LDPC codeword. G_{B} is a matrix multiplying a generator matrix for generating a codeword by an interleaving pattern, and, consequently, a result acquired by multiplying G_{B} by input information bits indicates a sequence having interleaved blocks of the LDPC codeword. That is, when the blocks are interleaved as shown in FIG. 17B, G_{B1}s is block #1, G_{B2}s is block #5, . . . , G_{B8}s is block #8.

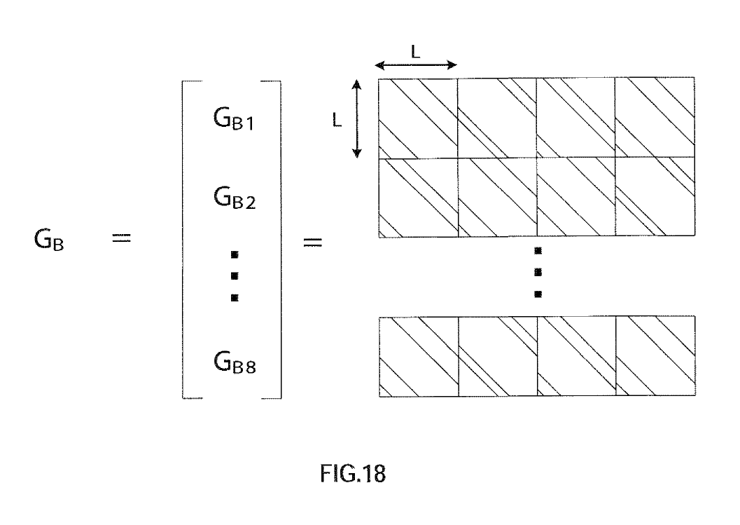

In this case, as shown in FIG. 3, when the check matrix is comprised of blocks in a unit of L×L submatrix acquired by cyclic shifts of the identity matrix, the generator matrix is also comprised of a block in a unit of L×L submatrix that is a sum of cyclic shifts of the identity matrix. For example, assume that G_{B2}, G_{B2}, . . . , G_{B8} are formed with four L×L matrices. In this case, G_{B} is as shown in FIG. 18.

As shown in FIG. 18, an L×L, matrix forming G_{B1}, G_{B2}, . . . , G_{B8} is in a form of a sum of cyclic shifts of the identity matrix. The present embodiment provides a configuration for performing LDPC coding and interleaving at the same time utilizing a characteristic that an L×L submatrix is a sum of the cyclic shifts.

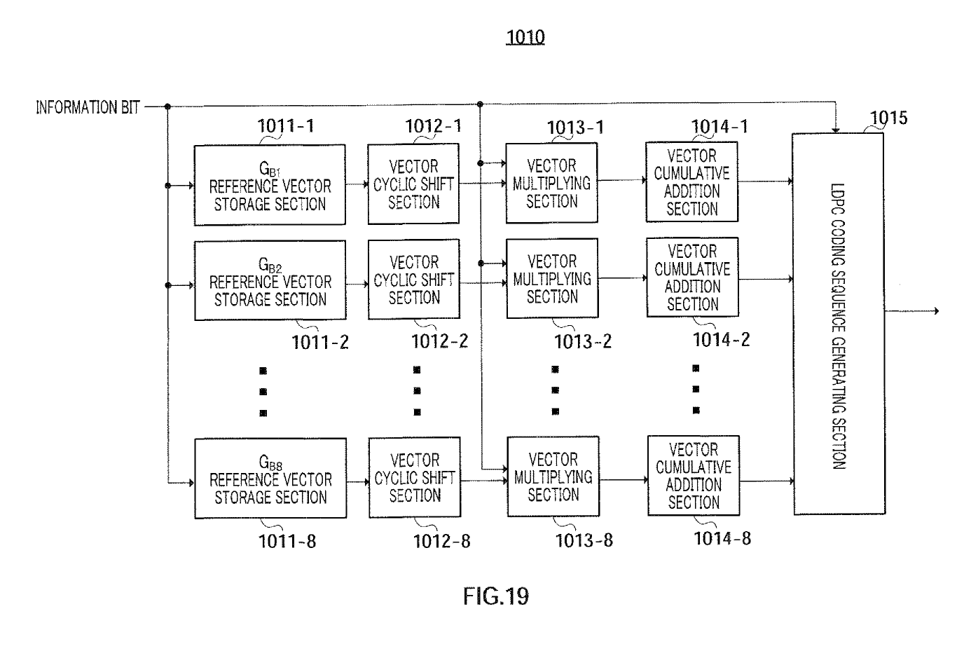

A configuration example of a coding apparatus that performs coding and interleaving for realizing coding and interleaving over a plurality of codes, will be described below. FIG. 19 shows a configuration example where LDPC coding and interleaving are performed over eight blocks.

Coding apparatus 1010 in FIG. 19 is provided with G_{B1} reference vector storage section 1011-1, G_{B2} reference vector storage section 1011-2, . . . , G_{B8} reference vector storage section 1011-8, vector cyclic shift sections 1012-1, 1012-2, . . . , 1012-8, vector multiplying sections 1013-1, 1013-2, . . . , 1013-8, vector cumulative addition sections 1014-1, 1014-2, . . . , 1014-8, and LDPC codeword sequence generating section 1015.

First, information bits inputted in coding and interleaving section 1010 are inputted in G_{B1} reference vector storage section 1011-1, G_{B2} reference vector storage section 1011-2, . . . , G_{B8} reference vector storage section 1011-8. These reference vector storage sections store reference vectors (e.g., first column vectors) in a matrix comprised of a sum of cyclic shifts of the L×L identity matrix forming G_{B1}, G_{B2}, . . . , G_{B8}. G_{B1} reference vector storage section 1011-1, G_{B2} reference vector storage section 1011-2, G_{B8} reference vector storage section 1011-8 output stored reference vectors upon receiving information bits as input. Here, an L×L matrix is a sum of cyclic shifts of the identity matrix, and, consequently, G_{B1} reference vector storage section 1011-1, G_{B2} reference vector storage section 1011-2, . . . , G_{B8} reference vector storage section 1011-8 switch reference vectors to be outputted every time L information bits are inputted.

Vector cyclic shift sections 1012-1, 1012-2, . . . , 1012-8 cyclically shift reference vectors outputted from G_{B1} reference vector storage section 1011-1, G_{B2} reference vector storage section 1011-2, . . . , G_{B8} reference vector storage section 1011-8, and output the cyclically shifted reference vectors to vector multiplying sections 1013-1, 1013-2, . . . , 1013-8. In this case, the method of cyclic shift is the same as in first cyclic shift sections 302-1, 302-2, . . . , 302-B. By this means, it is possible to generate vectors by which information bits are multiplied.

Vector multiplying sections 1013-1, 1013-2, . . . , 1013-8 receive as input the information bits and the outputs from vector cyclic shift sections 1012-1, 1012-2, . . . , 1012-8. Vector multiplying sections 1013-1, 1013-2, . . . , 1013-8 multiply the information bits and the outputs from vector cyclic shift sections 1012-1, 1012-2, . . . , 1012-8, and output the multiplication results to vector cumulative addition sections 1014.

Vector cumulative addition sections 1014-1, 1014-2, . . . , 1014-8 receive as input the outputs from vector multiplying sections 1013-1, 1013-2, . . . , 1013-8. Vector cumulative addition sections 1014-1, 1014-2, . . . , 1014-8 cumulatively add the input vectors and output the cumulative addition results to LDPC codeword sequence generating section 1015. Here, the cumulative addition is equivalent to the accumulation in vector cumulative addition section 304.

LDPC codeword sequence generating section 1015 receives as input the information bits and the outputs from vector cumulative addition sections 1014-1, 1014-2, . . . , 1014-8. LDPC codeword sequence generating section 1015 counts the number of times information bits are inputted, and outputs the outputs from vector cumulative addition sections 1014-1, 1014-2, . . . , 1014-8 as LDPC codewords at the time information bits having the number of bits for generating LDPC codewords are inputted. To be more specific, G_{B1}, G_{B2}, . . . , G_{B8} are each formed with four L×L matrices, and, consequently, the outputs from vector cumulative addition sections 1014-1, 1014-2, . . . , 1014-8 are outputted as LDPC codewords at the time 4×L information bits are inputted. The outputs from vector cumulative addition sections 1014-1, 1014-2, . . . , 1014-8 are equivalent to a multiplication result of 4×L information bits and G_{B} at the time 4×L information bits are inputted, so that it is possible to find interleaving results of the LDPC codewords.

An important point of the present embodiment is as follows. Interleaving of coding bits can be realized by multiplying coding bits by an interleaving pattern. Assume that a submatrix to be used in a generator matrix for generating LDPC codes is a sum of cyclic shifts of an identity matrix. Here, it is important that a cyclic shift of the identity matrix is made a submatrix of the interleaving pattern. As described above, there is only one element of “1” in each row in an interleaving pattern. Consequently, if a cyclic shift of an identity matrix is made a submatrix of the interleaving pattern, the submatrix of the interleaving pattern is comprised of a cyclic shift of the identity matrix or a zero matrix. In this case, a submatrix in a matrix acquired by multiplication of the interleaving pattern and a generator matrix for LDPC codes, is also a sum of cyclic shifts of the identity matrix. Therefore, it is possible to realize LDPC coding and interleaving of coding bits using the coding apparatus according to Embodiments 1 to 7. By this means, it is possible to reduce the circuit scale of the radio transmitting apparatus. As described above, it is important to make a cyclic shift of an identity matrix a submatrix in an interleaving pattern.

Further, interleaving over a plurality of LDPC codewords can be realized by multiplying a matrix coupling a plurality of generator matrices for generating LDPC codewords by an interleaving pattern. By making a submatrix in an interleaving pattern a cyclic shift of an identity matrix or zero matrix, it is possible to use the coding apparatus described in Embodiments 1 to 7. By performing interleaving over a plurality of LDPC codes, a drop of the signal power due to fading can be distributed, so that it is possible to reduce degradation of error correction upon decoding LDPC codes. Thus, a configuration interleaving a plurality of LDPC codes is important.

As described above, in the coding method according to the present embodiment for acquiring an LDPC codeword using a matrix comprised of a submatrix that is a sum of cyclic shifts of an identity matrix as a generator matrix, the method includes interleaving the LDPC codeword using an interleaving pattern matrix comprised of a submatrix that is a cyclic shift of the identity matrix, for example, providing submatrices in an interleaved matrix acquired by matrix calculations of the interleaving pattern matrix comprised of a submatrix that is a cyclic shift of the identity matrix and a generator matrix created using a check matrix in a form of a QC quasi lower triangular, and acquiring an LDPC codeword by linear calculations of the submatrices of the interleaved matrix and input data.

### Embodiment 11

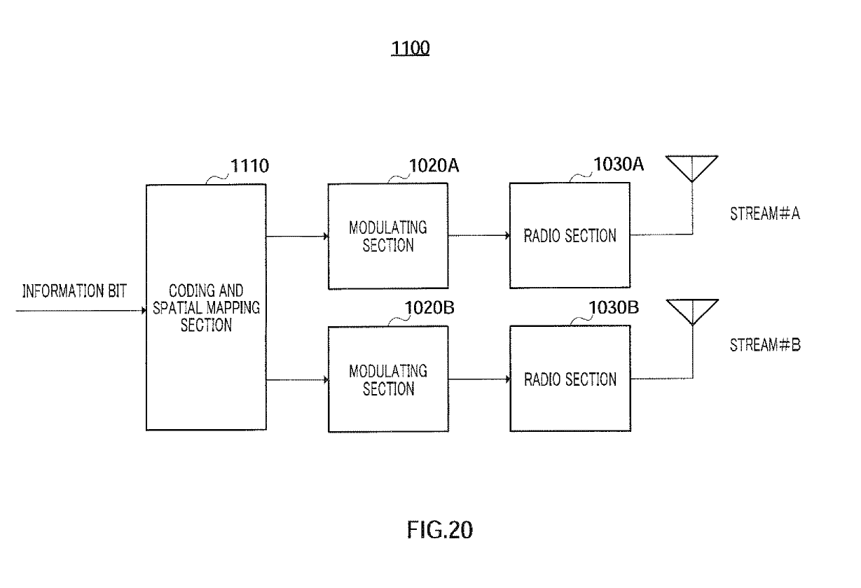

FIG. 20 shows the configuration of the multi-antenna according to the present embodiment. Further, the same components as in Embodiment 10 are assigned the same reference numerals and explanations will be omitted. Multi-antenna communication apparatus 1100 in FIG. 20 is provided with coding and spatial mapping section 1110, modulating sections 1020A and 1020B, and radio sections 1030A and 1030B. In FIG. 20, modulating section 1020A and radio section 1030A form stream #A and modulating section 1020B and radio section 1030E form stream #B. Information bits are inputted in coding and spatial mapping section 1110.

Coding and spatial mapping section 1110 performs LDPC coding and spatial mapping for the information bits. This LDPC coding and spatial mapping will be described later. Coding and spatial mapping section 1110 outputs the code bits after LDPC coding and spatial mapping, to modulating sections 1020A and 1020B.

Modulating sections 1020A and 1020B modulate the inputted code bits and output the results to radio sections 1030A and 1030B.

Radio sections 1030A and 1030B generate radio signals using the inputted modulation signals and output the results to radio channels.

Next, coding and spatial mapping section 1110 will be explained. Coding and spatial mapping section 1110 realizes LDPC coding and spatial mapping of the coding code bits with a single configuration. Here, the spatial mapping is equivalent to selecting a stream for transmitting the code bits after LDPC coding. When a matrix showing spatial mapping (spatial mapping pattern) is Γ, LDPC coding and spatial mapping can be expressed by equation 48.

$$\begin{matrix}( Equation 48 ) & \\ \begin{matrix}[ \begin{matrix}{y}_{1} \\ {y}_{2}\end{matrix} ] = Γ {G}_{l} s \\ = [ \begin{matrix}{Γ}_{11} + {Γ}_{12} \\ {Γ}_{21} + {Γ}_{22}\end{matrix} ] [ \begin{matrix}I \\ G\end{matrix} ] s\end{matrix} & [ 48 ]\end{matrix}$$

In [y₁ Y₂]^{T} in equation 48, y₁ represents the code bit assigned to stream #A and y₂ represents the code bit assigned to stream #B. Thus, by multiplying an LDPC codeword by Γ, it is possible to realize spatial mapping showing which code bit is assigned to which stream. Here, a multiplication result of spatial mapping Γ and generator matrix G₁ for generating an LDPC codeword is shown in equation 49.

$$\begin{matrix}( Equation 49 ) & \\ \begin{matrix}Γ {G}_{l} = [ \begin{matrix}{Γ}_{11} & {Γ}_{12} \\ {Γ}_{21} & {Γ}_{22}\end{matrix} ] [ \begin{matrix}I \\ G\end{matrix} ] \\ = [ \begin{matrix}{Γ}_{11} + {Γ}_{12} G \\ {Γ}_{21} + {Γ}_{22} G\end{matrix} ] \\ = {G}_{Y}\end{matrix} & [ 49 ]\end{matrix}$$

By multiplying input information bit s by G_{Y} shown in equation 49, it is possible to perform LDPC coding and spatial mapping at the same time. Here, assume that a cyclic shift of an identity matrix is a submatrix in spatial mapping pattern Γ. However, spatial mapping is an operation of assigning code bits to streams, and only one element of “1” is made to be in each row in spatial mapping pattern Γ. Therefore, a submatrix in spatial mapping pattern Γ is comprised of a cyclic shift of the identity matrix or a zero matrix. Further, as in Embodiment 10, a submatrix to be used in generator matrix G₁ for generating LDPC codewords is a sum of cyclic shifts of the identity matrix. In this case, the scale of the submatrix to be used in matrix Γ showing spatial mapping is the same as the scale of the submatrix of generator matrix G₁. When the above-noted spatial mapping pattern Γ is used, according to the relationship in equation 24 shown in this embodiment, a submatrix in G_{Y} of equation 49 is also a sum of cyclic shifts of an identity matrix. Therefore, coding and spatial mapping section 1110 according to the present embodiment can be formed with the coding apparatus used in Embodiments 1 to 7. That is, it is possible to perform LDPC coding and spatial mapping only with the configuration of the coding apparatus used in Embodiments 1 to 7. This provides an effect of reducing the circuit scale of multi-antenna communication apparatus 1100,

Further, the design of LDPC coding and spatial mapping will be described. As described in Embodiment 10, the effect of error correction upon decoding an LDPC codeword is given in one LDPC codeword. Therefore, to disperse errors caused by the drop of the fading fluctuation level in radio channels, the technique of dispersing the influence of fading fluctuation to a plurality of LDPC codewords is effective.

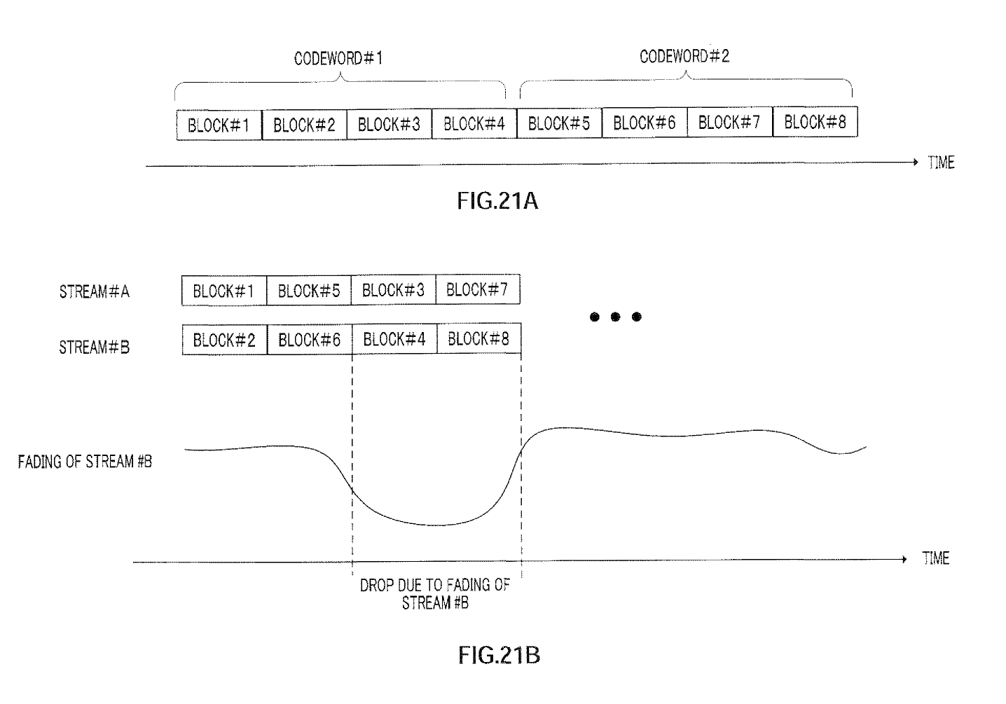

For example, as shown in FIG. 21A and FIG. 21B, spatial mapping is performed for two LDPC codewords, and the same fading fluctuation is dispersed to a plurality of LDPC codewords. However, a block in FIG. 21A and FIG. 21B is associated with the submatrix that is a sum of cyclic shifts of an identity matrix in matrix G_{Y} for performing LDPC coding and spatial mapping. That is, code bit sequences acquired by multiplication of inputted information bits and submatrices are expressed as blocks. As shown in FIG. 21B, when the fading characteristic in stream ##B drops in a given period, the drop of fading influences block #4 (of codeword #1) and block #8 (of codeword #2).

In this case, upon decoding codeword #1, block #4 is the only block to be influenced by the drop of fading. Similarly, upon decoding codeword #2, only block #8 is the only block to be influenced by the drop of fading. Therefore, a drop of the signal level caused by the drop of fading is distributed to a plurality of LDPC codewords, so that it is possible to reduce degradation of error correction performance upon decoding LDPC codes.

As described above, a spatial mapping pattern for performing spatial mapping over a plurality of LDPC codes can be expressed as shown in equation 50.

$$\begin{matrix}( Equation 50 ) & \\ Γ {G}_{L} = [ \begin{matrix}{Γ}_{11} & {Γ}_{12} & {Γ}_{13} & {Γ}_{14} \\ {Γ}_{21} & {Γ}_{22} & {Γ}_{23} & {Γ}_{24} \\ {Γ}_{31} & {Γ}_{32} & {Γ}_{33} & {Γ}_{34} \\ {Γ}_{41} & {Γ}_{42} & {Γ}_{43} & {Γ}_{44}\end{matrix} ] [ \begin{matrix}I \\ {G}_{1} \\ I \\ {G}_{2}\end{matrix} ] & [ 50 ]\end{matrix}$$

G_{L} shown in equation 50 shows a generator matrix for generating a plurality of LDPC codewords, and is the same as the one shown in equation 46. By multiplying this by matrix Γ for performing spatial mapping, it is possible to perform spatial mapping over a plurality of LDPC codes. As described above, by forming a submatrix in matrix Γ with a cyclic shift of an identity matrix or zero matrix, it is possible to use the coding apparatus used in Embodiments 1 to 7.

A case has been described with equation 50 where spatial mapping is performed over two LDPC codewords, to perform interleaving over three or more LDPC codewords, generator matrix G_{L} needs to be expanded and further coupled with a generator matrix for generating an LDPC codeword. A generator matrix to be coupled can be the same matrix or different matrix.

The configuration of coding and spatial mapping section 1110 will be described below. An example case will be explained below where, as shown in FIG. 21, two codewords are spatially mapped to streams #A and #B. According to the present embodiment, coding and spatial mapping section 1110 performs coding and spatial mapping at the same time. That is, the output from coding and spatial mapping section 1110 is spatially mapped. For example, blocks #1 and #2 in FIG. 21 are already distributed to modulation sections 1020A and 1020B, respectively, upon being outputted from coding and spatial mapping section 1110, and, similarly, blocks #5 and #6 are already distributed to modulation sections 1020A and 1020B, respectively, upon being outputted from coding and spatial mapping section 1110.

A case is assumed where the generator matrix and spatial mapping pattern used in coding and spatial mapping section 1110 are expressed by ΓG_{L} shown in equation 50. In this case, assume that ΓG_{L} is expressed as shown in equation 51.

$$\begin{matrix}( Equation 51 ) & \\ {G}_{S} = Γ {G}_{L} = [ \begin{matrix}{G}_{S 1} \\ {G}_{S 2}\end{matrix} ] & [ 51 ]\end{matrix}$$

As described above, a multiplication result of G_{S} in equation 51 and information bit s is equivalent to a spatially mapped sequence after LDPC coding. For example, as shown in equation 51, upon dividing G_{S} into two submatrices G_{S} and G_{S2} the results of multiplying G_{S1} by information bit s are made blocks of the LDPC codeword spatially mapped to stream #A, and, similarly, the results of multiplying G_{S2} by information bit s are made blocks of the LDPC codeword spatially mapped to stream ##B. By this means, it is possible to perform LDPC coding and spatial mapping at the same time and reduce the circuit for spatial mapping.

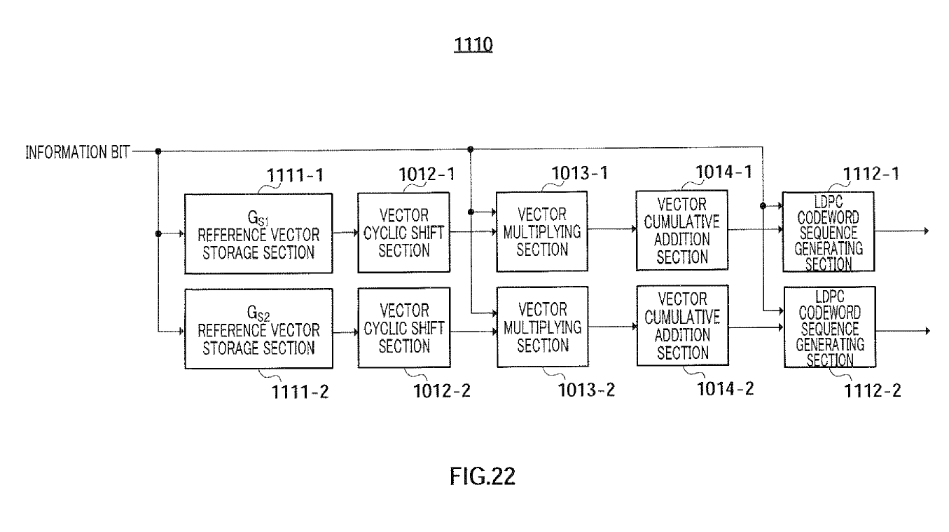

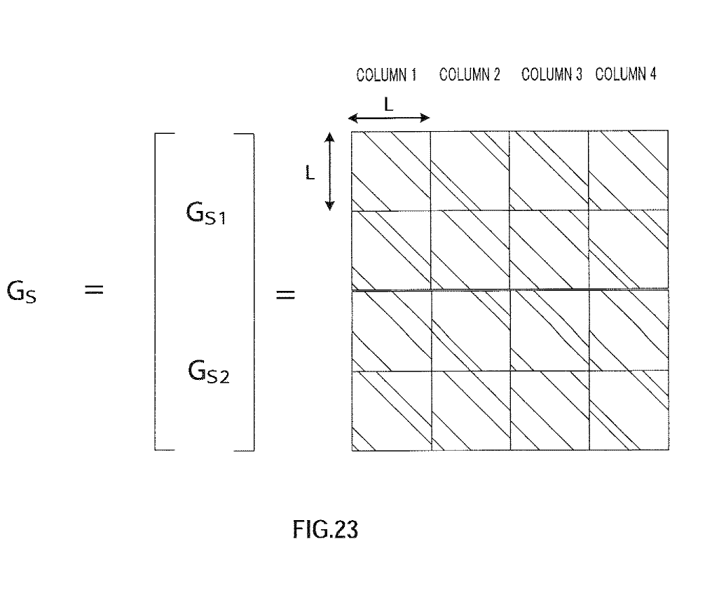

FIG. 22 illustrates a configuration example of coding and spatial mapping section 1110. Coding and spatial mapping section 1110 in FIG. 22 is a configuration example where spatial mapping is performed in two streams.

Coding and spatial mapping section 1110 is provided with G_{S1} reference vector storage section 1111-1, G_{S2} reference vector storage section 1111-2, vector cyclic shift sections 1012-1 and 1012-2, vector multiplying sections 1013-1 and 1013-2, vector cumulative addition sections 1014-1 and 1014-2, and LDPC codeword sequence generating sections 1112-1 and 1112-2.

Information bits inputted in coding and spatial mapping section 1110 are inputted in G_{S1} reference vector storage section 1111-1 and G_{S2} reference vector storage section 1111-2. G_{S1} reference vector storage section 1111-1 and G_{S2} reference vector storage section 1111-2 store the reference vectors of G_{S1} and G_{S2} in equation 51, respectively. G_{S1} and G_{S2} are each formed with a matrix that is a sum of cyclic shifts of an identity matrix.

For example, assume that G_{S1} and G_{S2} are each formed with two L×L row matrices and four L×L column matrices. In this case, upon receiving as input information bits, G_{S1} reference vector storage section 1111-1 and G_{S2} reference vector storage section 1111-2 output the reference vectors of L×L matrices equivalent to the first column. Here, the outputted reference vectors are used to generate vectors by which information bits are multiplied, and G_{S1} reference vector storage section 1111-1 and G_{S2} reference vector storage section 1111-2 switch the reference vectors for output, to the reference vectors of L×L matrices in the second column, reference vectors of L×L matrices in the third column, . . . , every time L information bits are inputted.

As in Embodiment 10, vector cyclic shift sections 1012-1 and 1012-2 cyclically shift in order the reference vectors outputted from G_{S1} reference vector storage section 1111-1 and G_{S2} reference vector storage section 1111-2, generate vectors by which information bits are multiplied, and output the generated vectors to vector multiplying sections 1013-1 and 1013-2.

Vector multiplying sections 1013-1 and 1013-2 multiply the vectors outputted from vector cyclic shift sections 1012-1 and 1012-2 and the information bits, and output the multiplication results to vector cumulative addition sections 1014-1 and 1014-2.

Vector cumulative addition sections 1014-1 and 1014-2 cumulatively add the vectors outputted from vector multiplying sections 1013-1 and 1013-2, and output the cumulative addition results to LDPC codeword sequence generating sections 1112-1 and 1112-2.

LDPC codeword sequence generating sections 1112-1 and 1112-2 output the output vectors from vector cumulative addition sections 1014-1 and 1014-2 at the time all information bits are inputted (in this example, at the time 4×L information bits are inputted), as LDPC codes after spatial mapping. The output from LDPC codeword sequence generating section 1112-1 is the LDPC codeword to be transmitted in stream #A and the output from LDPC codeword sequence generating section 1112-2 is the LDPC codeword to be transmitted in stream #B.

As described above, by using a matrix multiplying in advance a spatial mapping pattern and a generator matrix for generating LDPC codewords, it is possible to perform LDPC coding and spatial mapping at the same time without using a circuit for performing spatial mapping.

The important points of the present embodiment are as follows. In a multi-antenna communication apparatus, it is possible to realize spatial mapping by multiplication of matrices. In this case, it is important to make a cyclic shift of the identity matrix a submatrix in a matrix for spatial mapping. When a submatrix in a generator matrix for generating LDPC codewords is a sum of cyclic shifts of the identity matrix, in a submatrix in a matrix acquired by multiplication of the matrix for spatial mapping and the generator matrix is also a sum of cyclic shifts of the identity matrix. In this case, by using the coding apparatus used in Embodiments 1 to 7, it is possible to perform LDPC coding and spatial mapping at the same time. Therefore, there is an advantage of reducing the scale circuit of a multi-antenna communication apparatus.

Further, to reduce degradation of error correction performance of LDPC codewords due to a drop of the level of fading fluctuation, it is important to perform spatial mapping over a plurality of LDPC codewords. In this case, to distribute a drop of the level of fading fluctuation, as shown in FIG. 21B, by arranging different codewords in the time domain, it is possible to acquire a high dispersion effect.

### Embodiment 12

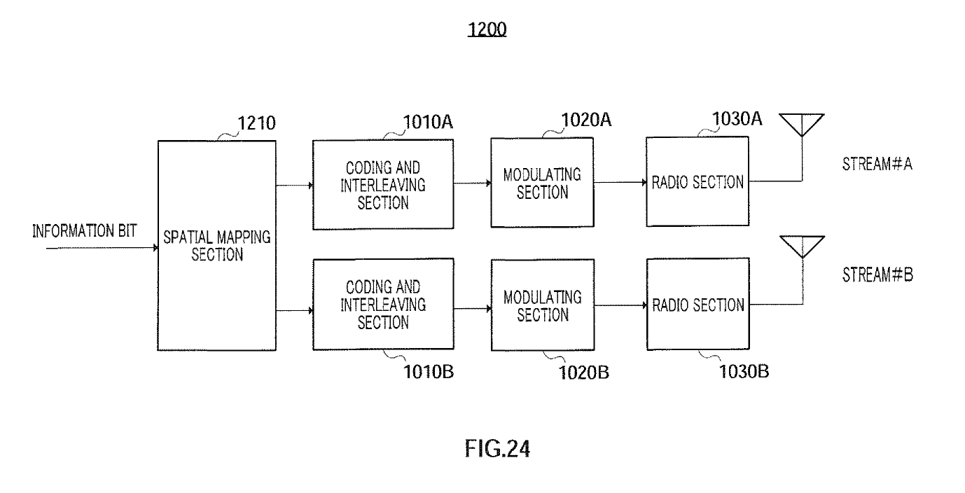

The present embodiment relates to LDPC coding and interleaving of code bits after coding in a multi-antenna communication apparatus. FIG. 24 illustrates a configuration example of the multi-antenna communication apparatus according to the present embodiment. Further, in FIG. 24, the same components as in FIG. 20 are assigned the same reference numerals and explanations will be omitted.

Multi-antenna communication apparatus 1200 in FIG. 24 employs a configuration replacing coding and spatial mapping section 1110 in multi-antenna communication apparatus 1100 in FIG. 20 with spatial mapping section 1210, and further having coding and interleaving sections 1010A and 1010B.

Information bits are inputted in spatial mapping section 1210. Spatial mapping section 1210 distributes the inputted information bits to streams #A and #B. For example, spatial mapping section 1210 outputs information bits inputted at a given time to stream #A and outputs information bits inputted at next time to stream #B. Afterwards, similarly, spatial mapping section 1210 outputs the inputted information bits to streams #A and #B alternately.

The spatially mapped information bits are inputted in coding and interleaving sections 1010A and 1010B. Coding and interleaving sections 1010A and 1010B perform LDPC coding of the inputted information bits and interleave the coding code bits. Coding and interleaving sections 1010A and 1010B output the interleaved code bits to modulating sections 1020A and 1020B.

Modulating sections 1020A and 1020B modulate the inputted code bits and generate modulation signals. Modulating sections 1020A and 1020B output the generated modulation signals to radio sections 1030A and 1030B.

Radio sections 1030A and 1030B generate radio signals using the inputted modulation signals, and output the radio signals to radio channels.

Coding and interleaving sections 1010A and 1010B employ the same configuration as coding and interleaving section 1010 shown in Embodiment 10. As shown in Embodiment 10, a submatrix in a generator matrix for generating LDPC codewords is a sum of cyclic shifts of an identity matrix. Further, a cyclic shift of the identity matrix is made a submatrix in an interleaving pattern. By this means, a submatrix in the matrix (i.e., an interleaved matrix) acquired as a result of multiplying the two above-noted matrices is also a sum of cyclic shifts of the identity matrix. Therefore, coding and interleaving sections 1010A and 1010B can employ the configuration of the coding apparatus described in Embodiments 1 to 7. By this means, multi-antenna communication apparatus 1200 can realize LDPC coding and interleaving of code bits after LDPC coding, with a single configuration.

Another effect by employing the configuration according to the present embodiment will be described. As shown in the present embodiment, multi-antenna communication apparatus 1200 has coding and interleaving sections 1010A and 1010B. In this case, coding and interleaving sections 1010A and 1010E can use respective generator matrices for generating LDPC codewords and respective interleaving patterns.

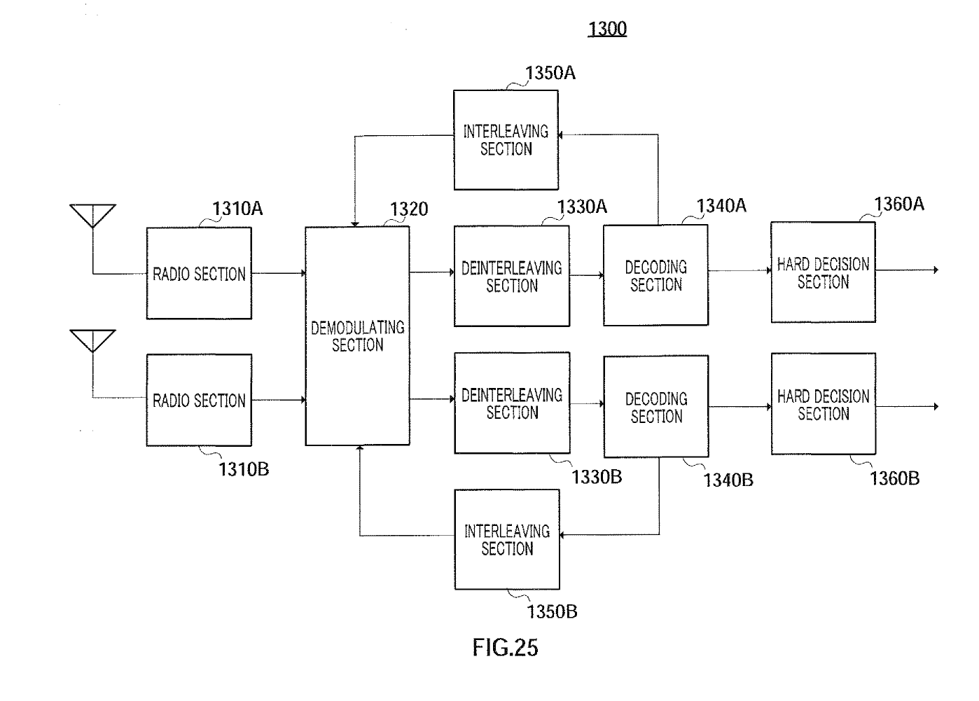

BICM (Bit Interleaved Coded Modulation) decoding using respective generator matrices and respective interleaving patterns will be explained. First, BICM decoding in MIMO communication is as shown in Non-Patent Document 5. FIG. 25 illustrates a configuration example of a multi-antenna communication apparatus that performs BICM decoding. Further, FIG. 25 illustrates the main components on the receiving side.

Multi-antenna communication apparatus 1300 in FIG. 25 is provided with radio sections 1310A and 1310B, demodulating section 1320, deinterleaving sections 1330A and 1330B, decoding sections 1340A and 1340B, and interleaving sections 1350A and 1350B.

Received spatial multiplex signals are inputted in radio sections 1310A and 1310B. Radio sections 1310A and 1310B perform down-conversion on the received signals and output the received signals after down-conversion to demodulating section 1320.

Demodulating section 1320 demodulates the signals outputted from radio sections 1310A and 1310B by BICM decoding.

In BICM decoding, demodulation is performed using the log posterior probability ratio with respect to the bits mapped to a received signal. A method of calculating the log posterior probability ratio is disclosed in Non-Patent Document 5. Demodulating section 1320 outputs the log posterior probability ratio with respect to the bits mapped to the received signal, to deinterleaving sections 1330A and 1330B.

Deinterleaving sections 1330A and 1330B deinterleave the inputted log posterior probability ratio and output the deinterleaved log posterior probability ratio to decoding section 1340A and 1340B. Here, deinterleaving is equivalent to the operation of returning the order of code bits changed by interleaving in coding and interleaving sections 1010A and 1010B of multi-antenna communication apparatus 1200, to the original order.

Decoding sections 1340A and 1340B decodes LDPC codes using the inputted log posterior probability ratio. Here, what is acquired upon decoding is the log posterior probability ratio with respect to the LDPC code bits. Decoding sections 1340A and 1340B output the log posterior probability ratio acquired by decoding the LDPC codes, to interleaving sections 1350A and 1350B.

Interleaving sections 1350A and 1350B interleaves the inputted log posterior probability ratio and output the interleaved log posterior probability ratio to demodulating section 1320.

Demodulating section 1320 demodulates the received signals again using the inputted log posterior probability ratio. Demodulating section 1320 outputs the log posterior probability ratio given by demodulating the received signals, to deinterleaving sections 1330A and 1330B. Non-Patent Document 5 discloses a method of repeating demodulation and decoding.

Demodulating section 1320 and decoding sections 1340A and 1340B performs demodulation and decoding for predetermined iterative times and output the log posterior probability ratio with respect to LDPC code bits acquired upon the final decoding, to hard decision sections 1360A and 1360B. Hard decision sections 1360a and 1360B perform hard decisions using the log posterior probability ratio with respect to LDPC code bits outputted from decoding sections 1340A and 1340B. Hard decision sections 1360A and 1360B output the decoding bits acquired by the hard decisions as information bits. By this means, multi-antenna communication apparatus 1300 can acquire the information bits from the received signals.

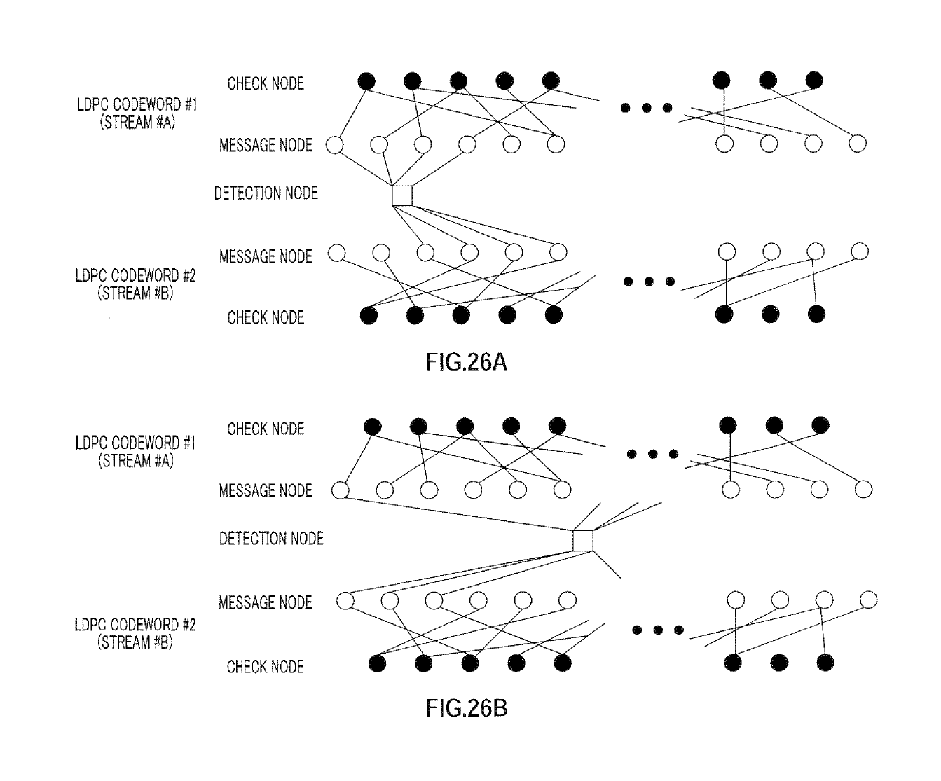

Further, FIG. 26A and FIG. 26B illustrate factor graphs where generator matrices for generating LDPC codewords and interleaving patterns for codewords are different in BICM decoding. A factor graph is made by graphing a situation where information is exchanged between function nodes and variable nodes. In BICM decoding, demodulation and decoding are performed, and the factor graphs in FIG. 26A and FIG. 26B show detection nodes that perform demodulation processing, and check nodes and message nodes that perform decoding processing. Further, Non-Patent Document 6 discloses information exchange between check nodes and message nodes upon decoding LDPC codes using sum-product decoding. Further, FIG. 26A illustrates a factor graph at time 1 and FIG. 26B illustrates a factor graph at time 2.

As shown in FIG. 26A and FIG. 26B, the factor graph shows check nodes, message nodes and branches connecting these nodes of LDPC codeword #1 transmitted in stream #A, and check nodes, message nodes and branches connecting these nodes of LDPC codeword #2 transmitted in stream #B. In FIG. 26A and FIG. 26B, the decoding of LDPC codes in decoding section 1340A is equivalent to decoding of LDPC codeword #1, and the decoding of LDPC codes in decoding section 13408 is equivalent to the decoding of LDPC codeword #2.

In decoding processing of LDPC codes, information is exchanged between check nodes and message nodes. On the other hand, demodulating processing by BICM decoding is performed in the detection node. In demodulating, the log posterior probability ratio with respect to bits mapped to a received signal is calculated. The bits mapped to the received signal can be associated with code bits in the LDPC codeword. In the factor graph, the code bits in the LDPC codeword are associated with message nodes. The factor graphs shown in FIG. 26A and FIG. 26B illustrate branches between bits (message nodes) demodulated at a given time and detection node. The factor graphs shown in FIG. 26A and FIG. 26B illustrate a situation where the detection node performs demodulation using information acquired from message nodes and gives the log posterior probability ratios acquired by demodulation, to message nodes. Further, when modulating sections 1020A and 1020E of multi-antenna communication apparatus 1200 use a 16 QAM modulation scheme, four bits are mapped to a received signal, and therefore the number of message nodes to which the detection nodes in the factor graphs in FIG. 26A and FIG. 26B give log posterior probability ratio, is four. Thus, cases are exemplified in FIG. 26A and FIG. 26B where the 16QAM modulation scheme is used.

According to the present embodiment, coding and interleaving sections 1010A and 1010B use respective generator matrices, and, consequently, the connection relationships of branches (edges) between check nodes and message nodes are different, between LDPC codeword #1 and LDPC codeword #2. Further, coding and interleaving sections 1010A and 1010B use respective interleaving patterns, and, consequently, the connection relationships of branches between the detection node and message nodes in LDPC codeword #1 are different from the connection relationships of branches between the detection node and message nodes in LDPC codeword #2.

As known from the fact that the connection relationships between check nodes and message nodes are different between LDPC codeword #1 and LDPC codeword #2, the distribution of the accuracy of log posterior probability ratios of code bits acquired by decoding an LDPC codeword is different. For example, in decoding using sum-product decoding, information is exchanged between check nodes and message nodes, and a log posterior probability ratio with respect to code bits is updated. When the connection relationships between check nodes and message nodes are different, the log posterior probability ratio is updated in different information paths, and, consequently, the distribution of log posterior probability ratios with respect to code bits is different.

In BICM decoding, demodulation is performed again using a log posterior probability ratio with respect to code bits acquired by decoding an LDPC codeword. LDPC codeword #1 and LDPC codeword #2 are interleaved using respective interleaving patterns, and, consequently, the distribution of log posterior probability ratios acquired in the detection node from message nodes is further randomized. Thus, the distribution of the log posterior probability ratios used in the detection node is randomized, so that it is possible to provide a time diversity effect and improve demodulation performance.

As described above, in a multi-antenna communication system, by varying the generator matrix to be used for LDPC coding per stream spatially multiplexed, and varying the interleaving pattern per stream, it is possible to improve performance of BICM decoding of a received signal.

Thus, in the coding method according to the present embodiment for acquiring an LDPC codeword using as a generator matrix a matrix comprised of a submatrix that is a sum of cyclic shifts of the identity matrix, the method includes: spatially mapping an LDPC codeword using a spatial mapping pattern comprised of a submatrix that is a cyclic shift of an identity matrix; for example, providing submatrices of a coding and spatial mapping matrix acquired by matrix calculations between a spatial mapping pattern matrix comprised of a submatrix that is a cyclic shift of the identity matrix and a generator matrix created using a QC quasi lower triangular check matrix; and acquiring an LDPC codeword by linear calculations of submatrices in the coding and spatial mapping matrix and input data.

Further, as in Embodiment 10, coding and interleaving sections 1010A and 1010B can perform interleaving over a plurality of codewords. In this case, it is possible to provide the time diversity effect and improve receiving performance.

### Embodiment 13

A configuration is provided with Embodiment 11 where coding and spatial mapping are performed at the same time. Further, by spatially mapping LDPC codewords as shown in Embodiment 12, the influence of fading is distributed to a plurality of codewords, and a time diversity effect is acquired. According to the present embodiment, it is possible to provide spatial diversity effect in addition to time diversity effect.

The configuration of the multi-antenna communication apparatus according to the present embodiment is the same as multi-antenna communication apparatus 1100 in FIG. 20 described in Embodiment 11. The present embodiment is different from Embodiment 11 in a spatial mapping method in coding and spatial mapping section 1110.

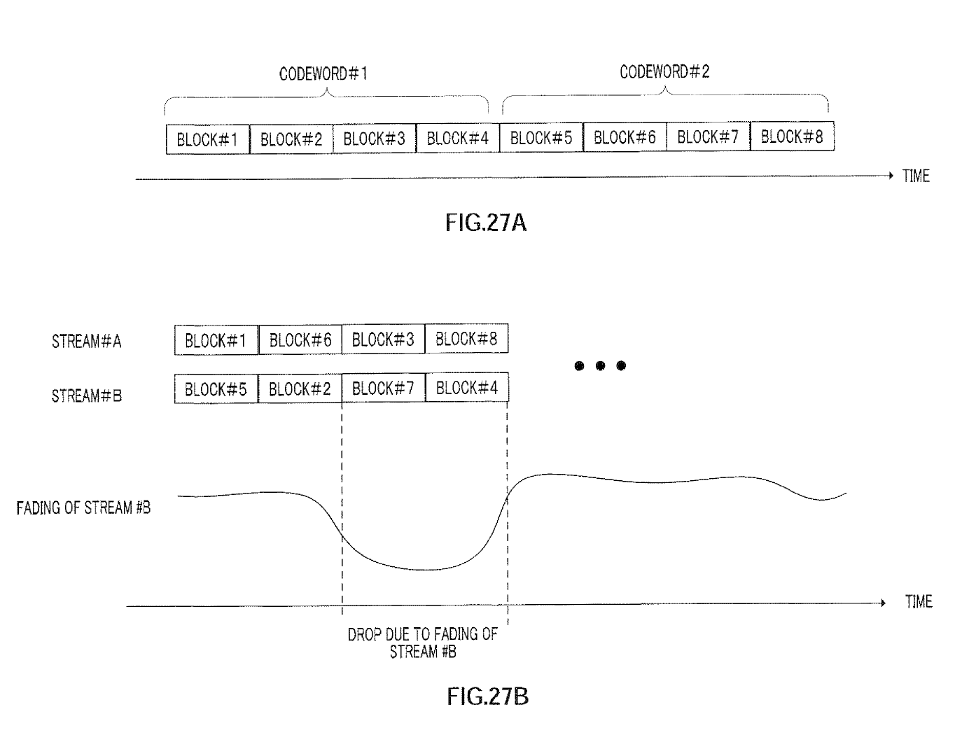

The spatial mapping according to the preset embodiment will be explained below using FIG. 27. As shown in FIG. 27A, a case will be explained where two LDPC codes, namely, codeword #1 and codeword #2 are formed with blocks #1, #2, #3 and #4 and blocks #5, #6, #7 and #8, respectively.

As shown in FIG. 27B, coding and spatial mapping section 1110 spatially map LDPC codewords such that different codewords are spatially mapped in streams #A and #B at the same time.

Further, coding and spatial mapping section 1110 spatially maps blocks such that blocks of different codewords in the time domain are spatially mapped in the same stream. For example, as shown in stream #A in FIG. 273, block #1 (codeword #1) is spatially mapped at a given time and block #6 (codeword #2) is spatially mapped at the next time.

When the spatial mapping is performed, for example, by performing BICM decoding of received signals as in Embodiment 12, it is possible to improve demodulation performance. This is based on the following principles.

Codeword #1 and codeword #2 each are separately subjected to LDPC decoding. That is, error correction effects are acquired in codewords #1 and #2, separately. As described above, demodulation is performed for BICM decoding of received signals. In this case, the codewords spatially mapped in streams #A and #B at the same time are different. For example, when block #1 (codeword #1) is spatially mapped in stream #1, block #5 (codeword #2) is spatially mapped in stream #B. In this case, error correction effects by codewords #1 and codeword #2 are reflected to the pair of codewords upon demodulation. That is, the log posterior probability ratio with respect to code bits given by decoding codeword #1 is used to find the log posterior probability ratio with respect to bits mapped to blocks of codeword #1 and blocks of codeword #2. Similarly, the log posterior probability ratio with respect to code bits given by decoding codeword #2 is used to find the log posterior probability ratio with respect to bits mapped to the blocks of codeword #1 and the blocks of codeword #2. Thus, by spatially mapping different codewords at the same time, it is possible to provide spatial diversity effect.

Further, in the same stream, by spatially mapping blocks of different codewords in the time domain, it is possible to provide time diversity effect. This is based on the same principles as shown in Embodiments 10 and 11. That is, a drop of receiving power due to fading is dispersed to a plurality of codewords, so that it is possible to improve error correction effect.

As described above, the present embodiment relates to spatial mapping of LDPC codewords. Further, even when the configuration of multi-antenna communication apparatus 1200 shown in Embodiment 12, it is possible to realize the same spatial mapping of LDPC codewords as in the present embodiment. Coding and interleaving sections 1010A and 1010B shown in the present embodiment realize coding and interleaving at the same time by multiplying inputted information bits and generator matrices. Therefore, generator matrices used in coding and interleaving sections 1010A and 1010B may be changed such that blocks of LDPC codewords are mapped in each stream as shown in FIG. 27B.

The disclosures of Japanese Patent Application No. 2006-235204, filed on Aug. 31, 2006, and Japanese Patent Application No. 2007-224621, filed on Aug. 30, 2007, including the specifications, drawings and abstracts, are incorporated herein by reference in their entirety.

### INDUSTRIAL APPLICABILITY

The coding method, coding apparatus and transmitting apparatus of the present invention are useful as, for example, a coding method, coding apparatus and transmitting apparatus for performing error correction according to a check matrix of LDPC (Low Density Parity Check) codes in a radio communication system.

1. A coding method for performing low density parity check coding, comprising:
a providing step of providing a submatrix in a generator matrix created using a check matrix in a form of a quasi cyclic quasi lower triangular matrix; and
a linear calculation step of acquiring a low density parity check codeword by a linear calculation of the submatrix in the generator matrix and input data.

2. The coding method according to claim 1, wherein the submatrix in the generator matrix is expressed by a sum of cyclic shifts of an identity matrix.

3. The coding method according to claim 1, wherein the linear calculation step comprises acquiring parity data by cyclically shifting partial submatrices in the generator matrix, multiplying cyclically shifted vectors and the input data, and further cumulatively adding multiplied vectors.

4. The coding method according to claim 1, wherein the providing step comprises providing the submatrix in the generator matrix sequentially by cyclically shifting a first column vector of the submatrix in the generator matrix.

5. The coding method according to claim 1, wherein the linear calculation step comprises acquiring parity data from a multiplication result of a column vector of the generator matrix and input vector generated from the input data.

6. The coding method according to claim 1, wherein the linear calculation step comprises acquiring parity data by cumulatively adding a multiplication result of the column vector of the generator matrix and the input data.

7. The coding method according to claim 4, wherein:
the first column vector of the submatrix in the generator matrix is specified by an index; and
the providing step comprises reproducing the first column vector used in a cyclic shift using the index.

8. The coding method according to claim 1, wherein, when the input data comprises a plurality of bit sequences, the providing step comprises providing the submatrix in the generator matrix sequentially by cyclically shifting a column vector of the generator matrix by the number of the plurality of bit sequences.

9. The coding method according to claim 1, wherein the linear calculation step comprises outputting the parity data in response to an input of a control signal indicating a tail end of the input data.

10. A coding apparatus that performs low density parity check coding, comprising:
a providing section that provides a submatrix in a generator matrix created using a check matrix in a form of a quasi cyclic quasi lower triangular matrix; and
a linear calculating section that acquires a low density parity check codeword by a linear calculation of the submatrix in the generator matrix and input data.

11. The coding apparatus according to claim 10, further comprising:
a first storage section that stores the input data;
a second storage section that stores parity data acquired by the linear calculating section; and
an interleaving section that rearranges the stored input data and parity data.

12. The coding apparatus according to claim 10, further comprising a puncturing section that punctures the low density parity check codeword.

13. A coding method for performing low density parity check coding, comprising:
a providing step of providing an interleaved matrix acquired by a matrix calculation of an interleaving pattern matrix comprising a submatrix that is a cyclic shift of an identity matrix and a generator matrix created using a check matrix in a form of a quasi cyclic quasi lower triangular matrix; and
an linear calculation step of acquiring a low density parity check codeword by a linear calculation of the interleaved matrix and input data.

14. The coding method according to claim 13, wherein the linear calculation step comprises acquiring the low density parity check codeword by the linear calculation of the submatrix in the interleaved matrix and input data.

15. The coding method according to claim 14, wherein the generator matrix generates a plurality of low density parity check codewords, and the interleaving matrix is associated with a scale of the plurality of low density parity check codewords.

16. A coding apparatus comprising:
a providing section that provides a submatrix in an interleaved matrix acquired by a matrix calculation of an interleaving pattern matrix comprising a submatrix that is a cyclic shift of an identity matrix and a generator matrix created using a check matrix in a form of a quasi cyclic quasi lower triangular matrix;
a linear calculating section that acquires a low density parity check codeword by the linear calculation of the submatrix in the interleaved matrix and input data;
a modulating section that modulates the low density parity check codeword; and
a transmitting section that transmits a modulated signal acquired in the modulating section.

17. A coding method for performing low density parity check coding, comprising:
a providing step of providing a coding and spatial mapping matrix acquired by a matrix calculation of a spatial mapping pattern matrix comprising a submatrix that is a cyclic shift of an identity matrix and a generator matrix created using a check matrix in a form of a quasi cyclic quasi lower triangular matrix; and
a linear calculating step of acquiring a low density parity check codeword by a linear calculation of the coding and spatial mapping matrix and input data.

18. The coding method according to claim 17, wherein the linear calculation step comprises acquiring the low density parity check codeword by a linear calculation of the submatrix in the coding and spatial mapping matrix and the input data.

19. A transmitting apparatus comprising:
a providing section that provides a submatrix in a coding and spatial mapping matrix acquired by a matrix calculation of a spatial mapping pattern matrix comprising a submatrix that is a cyclic shift of an identity matrix and a generator matrix created using a check matrix in a form of a quasi cyclic quasi lower triangular matrix;
a linear calculating section that acquires a low density parity check codeword per stream by a linear calculation of the submatrix in the coding and spatial mapping matrix and input data;
a modulating section that modulates the low density parity check codeword per stream;
a transmitting section that transmits a modulation signal per stream acquired by the modulating section.

20. The transmitting apparatus according to claim 19, wherein the spatial mapping pattern matrix is a pattern in which blocks of the low density parity check codeword mapped to a same stream comprise blocks of different low density parity check matrices in a time domain.

21. A transmitting apparatus comprising:
a spatial mapping section that assigns input data to a plurality of streams by spatial mapping;
a providing section that provides a submatrix in an interleaved matrix acquired by a matrix calculation of an interleaving pattern matrix comprising a submatrix that is a cyclic shift of an identity matrix and a low density parity check codeword generator matrix comprising a submatrix that is a sum of the cyclic shifts of the identity matrix;
a coding and interleaving section that acquires a codeword per stream by a linear calculation of the submatrix in the interleaved generator matrix and the input data assigned to the plurality of streams;
a modulating section that modulates the codeword per stream; and
a transmitting section that transmits a modulation signal, acquired in the modulating section, per stream.

22. The transmitting apparatus according to claim 1, wherein a pattern of the low density parity check codeword generator matrix is different per stream.

23. The transmitting apparatus according to claim 21, wherein a pattern of the interleaving matrix is different per stream.

24. The transmitting apparatus according to claim 21, wherein the interleaving pattern matrix comprises a pattern in which blocks of the low density parity check matrix transmitted in a same stream comprise blocks of different low density parity check codewords in a time domain.

25. The transmitting apparatus according to claim 24, wherein the spatial mapping section assigns the input data such that low density parity check codeword blocks transmitted at a same time comprise blocks of different low density parity check codewords.

26. A coding method comprising:
a step of generating a low density parity check code using a generator matrix comprising a first submatrix that is a sum of cyclic shifts of an identity matrix; and
an interleaving step of interleaving the low density parity check code using an interleaving pattern comprising a second submatrix that is a cyclic shift of the identity matrix.

27. The coding method according to claim 26, wherein the interleaving step comprises multiplying a matrix coupling a plurality of generator matrixes and the interleaving pattern.
